(19) United States
(12) Patent Application Publication
(10) Pub. No.: US 2025/0311558 A1
(43) Pub. Date: Oct. 2, 2025

(54) DISPLAY PANEL

(71) Applicants: Hefei Visionox Technology Co., Ltd., Hefei (CN); VISIONOX TECHNOLOGY INC., Jiangsu (CN)

(72) Inventors: Zhiwei ZHOU, Hefei (CN); Jinfang ZHANG, Hefei (CN); Lu ZHANG, Hefei (CN)

(73) Assignees: Hefei Visionox Technology Co., Ltd., Hefei (CN); VISIONOX TECHNOLOGY INC., Jiangsu (CN)

(21) Appl. No.: 19/089,281

(22) Filed: Mar. 25, 2025

(30) Foreign Application Priority Data
Mar. 29, 2024 (CN) 202410382548.0
Oct. 31, 2024 (CN) 202411556001.4

(51) Int. Cl. H10K 59/122

(52) U.S. Cl. CPC H10K 59/122

(57) ABSTRACT

A display panel and a display device. The display panel includes an array substrate, an isolation structure, and light-emitting units. The array substrate includes a substrate and a metal structure disposed on the substrate. The isolation structure is disposed on a side of the array substrate. The isolation structure encloses and forms multiple isolation openings and multiple light-transmissive holes. An orthographic projection of a light-transmissive hole on the substrate is at least partially staggered from an orthographic projection of the metal structure on the substrate. The light-emitting units are configured to correspond to the multiple isolation openings. The orthographic projection of the light-transmissive hole on the substrate includes a recessed portion.

### CROSS-REFERENCE TO RELATED APPLICATION(S)

This application claims priority to Chinese Patent Application No. 202410382548.0, filed on Mar. 29, 2024, and Chinese Patent Application No. 202411556001.4, filed on Oct. 31, 2024, disclosures of both of which are incorporated herein by reference in its entirety.

### TECHNICAL FIELD

The present disclosure relates to the technical field of display devices and, in particular, to a display panel and a display device.

### BACKGROUND

An organic light-emitting diode (OLED) and a flat panel display device based on technologies such as a light-emitting diode (LED) have advantages such as high image quality, power saving, a thin body, and a wide application range. Therefore, the OLED and the flat panel display device are widely used in various consumer electronics such as a mobile phone, a television, a notebook computer, and a desktop computer, thereby becoming the mainstream display devices.

However, the use performance of a current OLED display product needs to be improved.

### SUMMARY

Embodiments of the present application provide a display panel and a display device to improve the use performance of the display panel.

Embodiments in a first aspect of the present application provide a display panel. The display panel includes an array substrate, an isolation structure, and light-emitting units. The array substrate includes a substrate and a metal structure disposed on the substrate. The isolation structure is disposed on a side of the array substrate. The isolation structure encloses and forms multiple isolation openings and multiple light-transmissive holes. An orthographic projection of a light-transmissive hole on the substrate is at least partially staggered from an orthographic projection of the metal structure on the substrate. The light-emitting units are configured to correspond to the multiple isolation openings. The orthographic projection of the light-transmissive hole on the substrate includes a recessed portion.

Embodiments in the first aspect of the present application further provide a display panel. The display panel includes an array substrate and an isolation structure. The array substrate includes a substrate and a metal structure disposed on the substrate. The isolation structure is disposed on a side of the array substrate. The isolation structure encloses and forms isolation openings and light-transmissive holes. An orthographic projection of a light-transmissive hole on the substrate is at least partially staggered from an orthographic projection of the metal structure on the substrate. The isolation opening is configured to accommodate at least part of a light-emitting unit. The light-transmissive holes include a first light-transmissive hole and a second light-transmissive hole. The first light-transmissive hole and the second light-transmissive hole are located on the peripheral side of the same isolation opening, and the shape of an orthographic projection of the first light-transmissive hole on the substrate is different from the shape of an orthographic projection of the second light-transmissive hole on the substrate.

Embodiments in the first aspect of the present application further provide a display panel. The display panel includes an array substrate, an isolation structure, and light-emitting units. The array substrate includes a substrate and a first active layer disposed on the substrate. The isolation structure is disposed on a side of the array substrate. The isolation structure encloses and forms multiple isolation openings and multiple light-transmissive holes. An orthographic projection of a light-transmissive hole on the substrate is staggered from an orthographic projection of the first active layer on the substrate. The light-emitting units are configured to correspond to the isolation openings.

Embodiments in the first aspect of the present application further provide a display panel. The display panel includes a substrate, a light-emitting layer, and an isolation structure. The light-emitting layer is located on a side of the substrate and includes multiple light-emitting units. At least part of the isolation structure encloses and forms isolation openings and light-transmissive holes. The isolation openings are configured to expose the light-emitting units. The light-transmissive hole is formed between at least part of the isolation openings, where the at least part of the isolation openings are adjacent to each other. The isolation structure includes first constant-width segments surrounding at least part of a light-transmissive hole. An orthographic projection of the first constant-width segment on the substrate is at least partially between an orthographic projection of a light-transmissive hole on the substrate and an orthographic projection of an isolation opening on the substrate. The first constant-width segment is configured to have a constant width. The width direction of the first constant-width segment refers to the direction in which one of the orthographic projection of the light-transmissive hole on the substrate and the orthographic projection of the isolation opening on the substrate points towards the other.

An embodiment in a second aspect of the present application further provides a display device. The display device includes the display panel in any one of the preceding embodiments in the first aspect.

The display panel provided by the embodiments of the present application includes the array substrate, the isolation structure, and the light-emitting units. The isolation structure encloses and forms the isolation openings and the light-transmissive holes. The isolation opening is configured to accommodate at least part of the light-emitting unit so that the mutual crosstalk between adjacent light-emitting units is reduced. Thus, the display panel emits light and performs a display. The array substrate includes the substrate and the metal structure disposed on the substrate. The metal structure may be configured to drive the light-emitting unit to emit light. The light-transmissive holes are configured to improve the transmittance of the display panel, thereby facilitating under-screen integration of a photosensitive module. The orthographic projection of the light-transmissive hole on the substrate is at least partially staggered from the orthographic projection of the metal structure on the substrate. Thus, the influence of the metal structure on the transmittance of the light-transmissive hole can be reduced. At least one light-transmissive hole includes a recessed portion. The distance between the recessed portion and an isolation opening may be configured to be relatively small so that the distribution area of the light-transmissive hole is increased as much as possible, thereby improving the use performance of the display panel.

### BRIEF DESCRIPTION OF DRAWINGS

FIG. 1 is a structural diagram of a display panel according to an embodiment of the present application;

FIG. 2 is a partial enlarged structural diagram of FIG. 1 in an example;

FIG. 3 is a cross-sectional view along A-A in FIG. 2 in an example;

FIG. 4 is a cross-sectional view along B-B in FIG. 2 in an example;

FIG. 5 is a partial enlarged structural diagram of FIG. 1 in another example;

FIG. 6 is a partial enlarged structural diagram of FIG. 5;

FIG. 7 is a partial enlarged structural diagram of FIG. 2;

FIG. 8 is a partial cross-sectional view of a display panel in an example;

FIG. 9 is a partial enlarged structural diagram of FIG. 1 in another example;

FIG. 10 is a structural diagram of a display panel according to an embodiment of the present application;

FIG. 11 is a partial top view of a display panel according to an embodiment of the present application;

FIG. 12 is a partial top view of a display panel according to an embodiment of the present application;

FIG. 13 is a partial top view of a display panel according to an embodiment of the present application;

FIG. 14 is a partial cross-sectional view of the display panel in FIG. 10;

FIG. 15 is a structural diagram of another display panel according to an embodiment of the present application;

FIG. 16 is a cross-sectional view along P-P′ in FIG. 15; and

FIG. 17 is a structural diagram of a display device according to an embodiment of the present application.

### DETAILED DESCRIPTION

Features and example embodiments in various aspects of the present application are described below in detail. The features, structures, or characteristics described below may be combined properly in one or more embodiments.

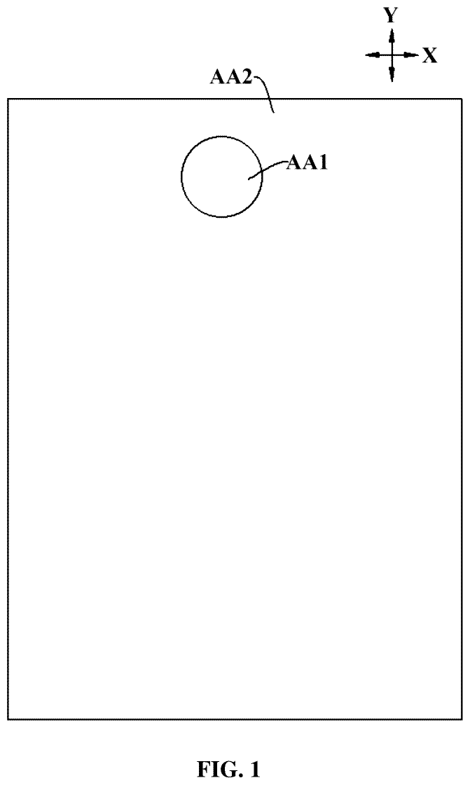

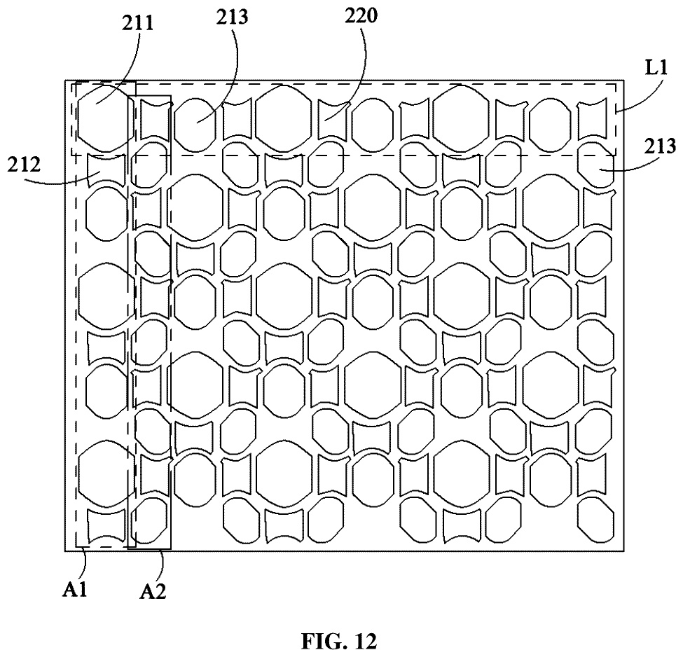

To better understand the present application, a display panel and a display device in embodiments of the present application are described below in detail with reference to FIGS. 1 to 17.

The technical solutions related to the following patents are provided for reference: CN118251982A, 202410864269.8, PCT/CN2024/098407, PCT/CN2024/102783, PCT/CN2024/098217, PCT/CN2024/100935, PCT/CN2024/102785, PCT/CN2024/099419, PCT/CN2024/099072, CN116685174A.

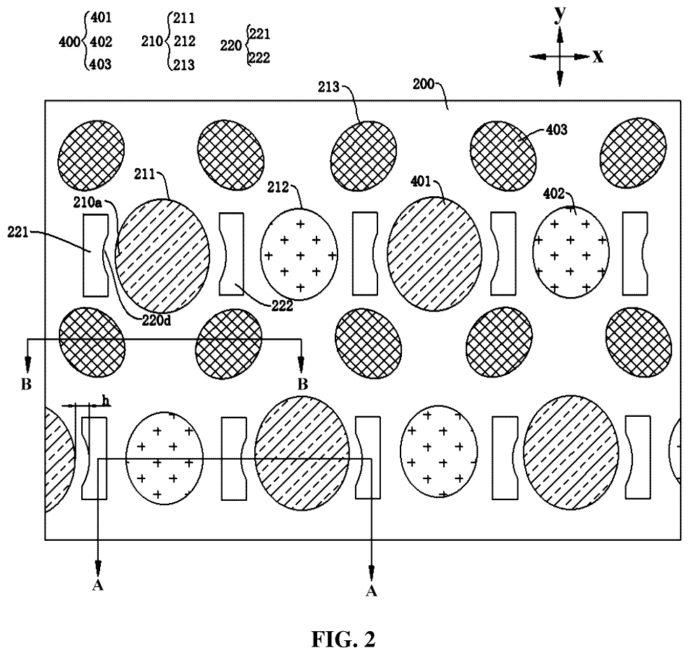

FIG. 1 is a structural diagram of a display panel according to an embodiment of the present application. FIG. 2 is a partial enlarged structural diagram of FIG. 1. FIG. 3 is a cross-sectional view along A-A in FIG. 2 in an example.

As shown in FIGS. 1 to 3, the embodiment of the present application provides a display panel. The display panel includes an array substrate 100, an isolation structure 200, and light-emitting units 400. The array substrate 100 includes a substrate 120 and a metal structure 110 disposed on the substrate 120. The isolation structure 200 is disposed on a side of the array substrate 100. The isolation structure 200 encloses and forms multiple isolation openings 210 and multiple light-transmissive holes 220. An orthographic projection of a light-transmissive hole 220 on the substrate 120 is at least partially staggered from an orthographic projection of the metal structure 110 on the substrate 120. The light-emitting units 400 are configured to correspond to the isolation openings 210. The orthographic projection of the light-transmissive hole 220 on the substrate 120 includes a recessed portion 220d.

Optionally, each light-emitting unit 400 of the light-emitting units 400 includes a first electrode 410, a light-emitting layer 420, and a second electrode 430 which are stacked in a direction away from the substrate 120. The light-emitting units 400 are configured to correspond to the isolation openings 210, which refers to that at least part of the light-emitting unit 400 is located in an isolation opening 210. For example, the light-emitting layer 420 of the light-emitting unit 400 and at least part of the second electrode 430 of the light-emitting unit 400 are located in the isolation opening 210.

In the embodiment of the present application, the display panel includes the array substrate 100 and the isolation structure 200. The isolation structure 200 encloses and forms the isolation openings 210 and the light-transmissive holes 220. The isolation opening 210 is configured to accommodate at least part of the light-emitting unit 400 so that the mutual crosstalk between adjacent light-emitting units 400 is reduced. Thus, the display panel emits light and performs a display. The array substrate 100 includes the substrate 120 and the metal structure 110 disposed on the substrate 120. The metal structure 110 may be configured to drive the light-emitting unit 400 to emit light. The light-transmissive holes 220 are configured to improve the transmittance of the display panel, thereby facilitating under-screen integration of a photosensitive module. The orthographic projection of the light-transmissive hole 220 on the substrate 120 is at least partially staggered from the orthographic projection of the metal structure 110 on the substrate 120. Thus, the influence of the metal structure 110 on the transmittance of the light-transmissive hole 220 can be reduced. At least one light-transmissive hole 220 includes a recessed portion 220d. The distance between an orthographic projection of the recessed portion 220d on the substrate 120 and an orthographic projection of an isolation opening 210 on the substrate 120 may be configured to be relatively small so that the distribution area of the light-transmissive hole 220 is increased as much as possible. Additionally, signal interference caused by excessive exposure of the metal structure 110 through the light-transmissive hole 220 is reduced, thereby improving the use performance of the display panel.

Optionally, in at least one group of a light-transmissive hole 220 and an isolation opening 210 which are adjacent to each other, the direction in which the center of one of the light-transmissive hole 220 and the isolation opening 210 points towards the center of the other one of the light-transmissive hole 220 and the isolation opening 210 is a preset direction. For example, the preset direction is an X direction in FIG. 2. The minimum spacing between an edge of the recessed portion 220d and an edge of the isolation opening 210 in the preset direction is greater than or equal to a preset distance h. Thus, the distance between the recessed portion 220d and the isolation opening 210 may be configured to be relatively small so that the distribution area of the light-transmissive hole 220 is increased as much as possible.

Optionally, along the preset direction, in the at least one group of the light-transmissive hole 220 and the isolation opening 210 which are adjacent to each other, for an orthographic projection of the light-transmissive hole 220 and an orthographic projection of the isolation opening 210 on the substrate 120, the orthographic projection of the isolation opening 210 on the substrate 120 includes a protruding portion 210a configured to correspond to the recessed portion 220d. Thus, the shapes of the isolation opening 210 and the light-transmissive hole 220 which are adjacent to each other are better adapted to each other so that the distribution area of the light-transmissive hole 220 is increased as much as possible.

Optionally, the shape of at least part of the protruding portion 210a is adapted to the shape of at least part of the recessed portion 220d so that the distribution area of the light-transmissive hole 220 is increased as much as possible.

Optionally, the light-transmissive holes 220 include a first light-transmissive hole 221 and a second light-transmissive hole 222. The first light-transmissive hole 221 and the second light-transmissive hole 222 are located on the peripheral side of the same isolation opening 210. An orthographic projection of the first light-transmissive hole 221 on the substrate 120 has a larger area than an orthographic projection of the second light-transmissive hole 222 on the substrate 120.

In these optional embodiments, generally, metal structures 110 corresponding to the peripheral side of the same isolation opening 210 in the array substrate 11 have different distribution areas. The orthographic projections of the first light-transmissive hole 221 and the second light-transmissive hole 222 of the light-transmissive holes 220 on the substrate have different areas. Thus, it is convenient for a user to reasonably set the dimension of the first light-transmissive hole 221 and the dimension of the second light-transmissive hole 222 according to the distribution of the metal structures 110 in the substrate so that the dimension of the first light-transmissive hole 221 and the dimension of the second light-transmissive hole 222 are better adapted to the distribution patterns of the metal structures 110 in the substrate. Thus, the distribution area of the light-transmissive hole 220 is increased as much as possible.

Optionally, a driver circuit is disposed in the array substrate 100. At least part of the metal structure 110 is configured to form the driver circuit. Optionally, orthographic projections of at least part of the light-transmissive holes 220 on the array substrate 100 are outside an orthographic projection of the driver circuit T on the array substrate 100.

The orthographic projection of the light-transmissive hole 220 on the substrate 120 is at least partially staggered from the orthographic projection of the metal structure 110 on the substrate 120, which refers to that the orthographic projection of the same light-transmissive hole 220 on the substrate is at least partially staggered from the orthographic projection of the metal structure 110 on the substrate 120 and at least part of the same light-transmissive hole 220 is configured to correspond to no metal structure 110. Optionally, the orthographic projection of the light-transmissive hole 220 on the substrate 120 may be outside the orthographic projection of the metal structure 110 on the substrate 120. Alternatively, the orthographic projections of part of the light-transmissive holes 220 on the substrate 120 may overlap the orthographic projection of the metal structure 110 on the substrate 120 while the other part of the orthographic projection of the light-transmissive hole 220 on the substrate 120 may be outside the orthographic projection of the metal structure 110 on the substrate 120.

Optionally, the display panel further includes a pixel defining layer 300. The pixel defining layer 300 is disposed on the array substrate 100 and includes pixel defining portions 310 and pixel openings 320 provided at the pixel defining portions 310. The pixel openings 320 communicate with the isolation opening 210. The light-emitting unit 400 is configured to correspond to a pixel opening and part of the structures of the light-emitting unit 400 are located in the pixel opening 320. The isolation structure 200 may be disposed on a side of the pixel defining portions 310 facing away from the array substrate 100. Alternatively, avoidance openings are provided on the pixel defining portions 310, and the isolation structure 200 may be located in the avoidance openings to be in direct contact with and directly connected to the array substrate 100. Optionally, the material of the pixel defining layer 300 may be an inorganic material so that the thickness of the pixel defining layer 300 can be appropriately reduced, thereby reducing the overall thickness of the display panel 10.

Optionally, the distance between at least part of an edge of the orthographic projection of the light-transmissive hole 220 on the array substrate 100 and at least part of an edge of an orthographic projection of the isolation opening 210 on the array substrate 100 is greater than or equal to the preset distance h. The mutual influence between the isolation opening 210 and the light-transmissive hole 220 can be reduced.

The preset distance h for the light-transmissive hole 220 has various value ranges. The preset distance h may be 3 μm to 4 μm, for example, 3 μm, 3.2 μm, 3.5 μm, 3.8 μm, or 4 μm so that the problem is alleviated that the preset distance h is too large and influences the opening area of the light-transmissive hole 220 or the preset distance h is too small and the light-transmissive hole 220 influences the position stability of the isolation opening 210. The preset distance h is not a fixed value due to actual process fluctuations, and upper and lower errors of the preset distance h are all within the scope.

The isolation structure 200 may be configured in various manners. As shown in FIG. 3, the isolation structure 200 may include a first sub-layer 201 and a second sub-layer 202 which are stacked in a direction away from the array substrate 100. An orthographic projection of the first sub-layer 201 on the array substrate 100 is within an orthographic projection of the second sub-layer 202 on the array substrate 100. That is, the second sub-layer 202 is configured to protrude from side edges of the first sub-layer 201. The dimension of the first sub-layer 201 is smaller than the dimension of the second sub-layer 202 so that recessed structures can be formed on a side of the second sub-layer 202 facing the substrate 120. When the light-emitting units 400 are subsequently prepared, a light-emitting material can be isolated by the isolation structure 200 to form the light-emitting units 400 which are independent of each other and correspond to the isolation openings 210.

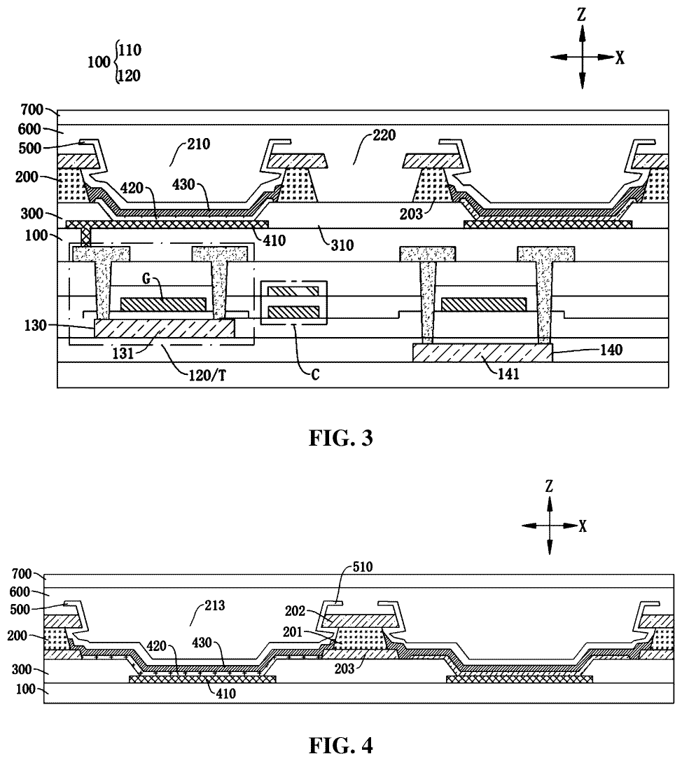

Optionally, as shown in FIG. 4, the isolation structure 200 may further include a third sub-layer 203 on a side of the first sub-layer 201 facing the array substrate 100. The orthographic projection of the first sub-layer 201 on the array substrate 100 is within an orthographic projection of the third sub-layer 203 on the array substrate 100. That is, the dimension of the first sub-layer 201 is smaller than the dimension of the third sub-layer 203. During the preparation of the first sub-layer 201, the third sub-layer 203 can protect a film on a side of the isolation structure 200 facing the array substrate 100.

Optionally, the light-emitting unit 400 includes the first electrode 410, the light-emitting layer 420, and the second electrode 430 which are stacked in the direction away from the array substrate 100. The first electrode 410 may be located on the array substrate 100 and in the pixel opening 320 or may be wrapped through a pixel defining portion 310 so that the first electrode 410 is exposed through the pixel opening 320. The light-emitting layer 420 is located in the pixel opening 320. Optionally, the material of the isolation structure 200 may include a conductive material and the second electrode 430 and the isolation structure 200 lap each other such that second electrodes 430 can be interconnected into a surface electrode through the isolation structure 200.

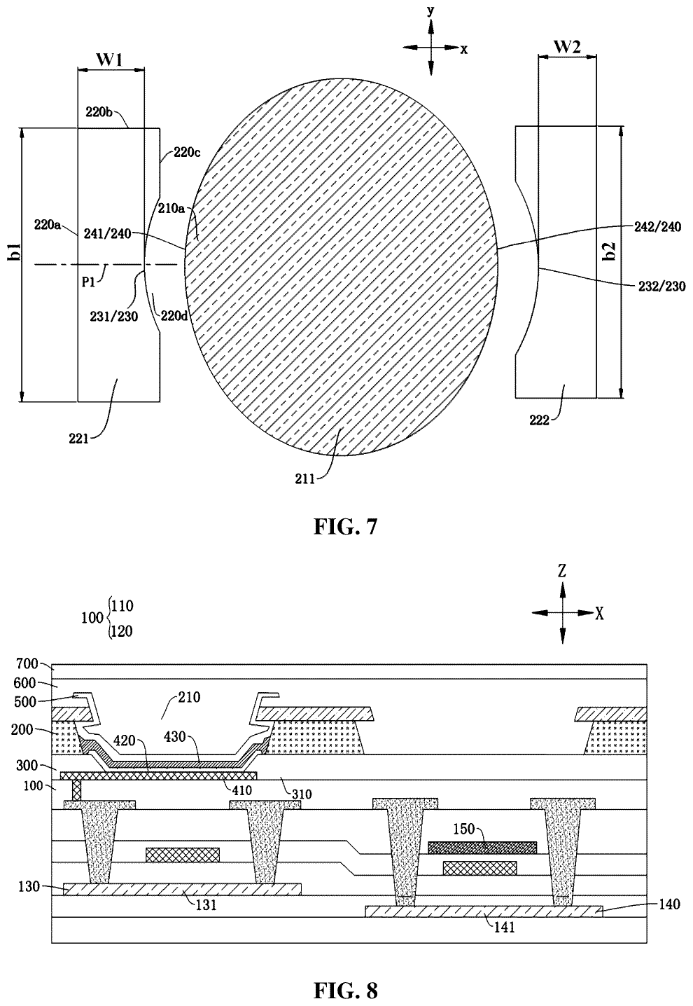

In some optional embodiments, for the light-transmissive hole 220 and the isolation opening 210 which are adjacent to each other, an orthographic projection of the recessed portion 220d on the substrate 120 has a first side edge 230 facing the orthographic projection of the isolation opening 210 on the substrate 120, an orthographic projection of the protruding portion 210a on the substrate 120 has a second side edge 240 facing the first side edge 230, and the distance between the first side edge 230 and the second side edge 240 is the preset distance h, as shown in FIGS. 2 and 7.

In these optional embodiments, the recessed portion 220d is recessed to form the first side edge 230, and the protruding portion 210a protrudes to form the second side edge 240. The minimum distance between the first side edge 230 and the second side edge 240 along the preset direction is greater than or equal to the preset distance h. Thus, the distance between the first side edge 230 and the second side edge 240 is relatively small so that the opening dimension of the light-transmissive hole 220 can be increased as much as possible.

Optionally, as shown in FIG. 7, the shape of the first side edge 230 is adapted to the shape of the second side edge 240 so that the distribution area of the light-transmissive hole 220 is increased as much as possible and the mutual influence between the light-transmissive hole 220 and the isolation opening 210 is reduced.

Optionally, the first side edge 230 and the second side edge 240 are equally spaced. The first side edge 230 and the second side edge 240 are equally spaced within a process error range. For example, the second side edge 240 is an arc-shaped edge which protrudes away from the center of the isolation opening 210 and the first side edge 230 is an arc-shaped edge which is recessed away from the center of the isolation opening 210 and towards the inside of the first light-transmissive hole 221 so that the first side edge 230 and the second side edge 240 can be equally spaced.

In these optional embodiments, the first side edge 230 and the second side edge 240 are equally spaced. Thus, it is ensured that the light-transmissive hole 220 has a sufficiently large distribution area, and the influence of the light-transmissive hole 220 on the isolation opening 210 can be reduced.

Optionally, the first side edge 230 and the second side edge 240 are arc-shaped. Optionally, to alleviate a diffraction phenomenon between light-emitting units 400 in different colors, the orthographic projection of the isolation opening 210 on the array substrate 100 is circular or elliptical. In the embodiment of the present application, description is performed using an example in which the orthographic projection of the isolation opening 210 on the array substrate 100 is elliptical, where the second side edge 240 is part of an ellipse. The first side edge 230 may be part of an ellipse. Thus, both the first side edge 230 and the second side edge 240 are arc-shaped and can be equally spaced.

Optionally, at least one of the first light-transmissive hole 221 and the second light-transmissive hole 222 may be provided with the first side edge 230.

Optionally, first side edges 230 include a first sub-edge 231 with which the first light-transmissive hole 221 is provided and a second sub-edge 232 with which the second light-transmissive hole 222 is provided, where both the first sub-edge 231 and the second sub-edge 232 face the isolation opening 210. The length of the first sub-edge 231 in a second direction Y is less than the length of the second sub-edge 232 in the second direction Y.

In these optional embodiments, the first light-transmissive hole 221 is provided with the first sub-edge 231, and the second light-transmissive hole 222 is provided with the second sub-edge 232. Additionally, the length of the first sub-edge 231 is less than the length of the second sub-edge 232 so that the distribution area of the first light-transmissive hole 221 is larger than the distribution area of the second light-transmissive hole 222.

Optionally, second side edges 240 include a third sub-edge 241 facing the first sub-edge 231 and a fourth sub-edge 242 facing the second sub-edge 232. The spacing between the first sub-edge 231 and the third sub-edge 241 may be equal to the spacing between the second sub-edge 232 and the fourth sub-edge 242. Alternatively, the spacing between the first sub-edge 231 and the third sub-edge 241 may be less than the spacing between the second sub-edge 232 and the fourth sub-edge 242 so that the first light-transmissive hole 221 and the second light-transmissive hole 222 are better adapted to the distribution patterns of the metal structures 110 in the array substrate 100.

The shape of the light-transmissive hole 220 may be overall a recessed polygon, where the first side edge 230 is one of the edges of the polygon.

Optionally, the inner wall of the light-transmissive hole 220 has the recessed portion 220d that is recessed away from the isolation opening 210. The first side edge 230 is disposed at the recessed portion 220d. In these optional embodiments, to adapt to the circular or elliptical isolation opening 210, the light-transmissive hole 220 may be provided with the recessed portion 220d and the first side edge 230 is disposed at the recessed portion 220d so that the first side edge 230 and the second side edge 240 are equally spaced.

In some embodiments, the light-transmissive hole 220 is located on a side of the isolation opening 210 in a first direction X. The light-transmissive hole 220 has a first straight edge 220a configured to face away from the first side edge 230 along the first direction X. The first straight edge 220a extends linearly along the second direction Y. The light-transmissive hole 220 is provided with one straight edge and one side edge so that the shape of the light-transmissive hole 220 is adapted to the shape of the isolation opening 210 and the dimension of the light-transmissive hole 220 can be increased as much as possible to increase the transmittance.

Optionally, two ends of the first straight edge 220a in the second direction Y are connected to second straight edges 220b, and the second straight edges 220b extend linearly along the first direction X to further simplify the distribution pattern of the light-transmissive hole 220. At least one of the first light-transmissive hole 221 and the second light-transmissive hole 222 may be provided with the second straight edges 220b.

Optionally, when the first light-transmissive hole 221 is provided with the first side edge 230 and includes the first sub-edge 231, the first sub-edge 231 and the first straight edge 220a are configured to face away from each other along the first direction X. Optionally, when the second light-transmissive hole 222 is provided with the first side edge 230 and includes the second sub-edge 232, the second sub-edge 232 and the first straight edge 220a are configured to face away from each other along the first direction X.

Optionally, the two ends of the first straight edge 220a in the second direction Y are connected to the second straight edges 220b, and the second straight edges 220b extend linearly along the first direction X to further simplify the distribution pattern of the light-transmissive hole 220. At least one of the first light-transmissive hole 221 and the second light-transmissive hole 222 may be provided with the second straight edges 220b.

Optionally, a third straight edge 220c is disposed on at least one side of the first side edge 230 in the second direction Y. The third straight edge 220c extends linearly along the second direction Y. The first side edge 230 is connected to the second straight edge 220b through the third straight edge 220c. When the first side edge 230 includes the first sub-edge 231, the first sub-edge 231 may be connected to the second straight edge 220b through the third straight edge 220c, and when the first side edge 230 includes the second sub-edge 232, the second sub-edge 232 may be connected to the second straight edge 220b through the third straight edge 220c so that the distribution area of the light-transmissive hole 220 is further increased and the shape of the light-transmissive hole 220 is simplified.

Optionally, the same light-transmissive hole 220 may include two third straight edges 220c. That is, the third straight edges 220c are each disposed on two sides of the first side edge 230 in the second direction Y and two ends of the first side edge 230 are connected to the second straight edges 220b through the third straight edges 220c so that the distribution area of the light-transmissive hole 220 is further increased. Optionally, two ends of the first sub-edge 231 may be connected to the second straight edges 220b through the third straight edges 220c. Optionally, two ends of the second sub-edge 232 may be connected to the second straight edges 220b through the third straight edges 220c.

Optionally, the first straight edge 220a has a first median line P1 extending along the first direction X. The first side edge 230 is symmetrically disposed with respect to the first median line P1 so that the shape of the light-transmissive hole 220 is further simplified. The first median line P1 passes the midpoint of the first straight edge 220a in the second direction Y and is formed by extending along the first direction X. Optionally, when the first light-transmissive hole 221 is provided with the first straight edge 220a, the first sub-edge 231 is symmetrically disposed with respect to the first median line P1, or when the second light-transmissive hole 222 is provided with the first straight edge 220a, the second sub-edge 232 is symmetrically disposed with respect to the first median line P1.

Optionally, when the light-transmissive hole 220 includes the first side edge 230, the first side edge 230 is located on the side of the light-transmissive hole 220 facing a first isolation opening 211. The first isolation opening 211 typically has a relatively large distribution area. The first side edge 230 is located on the side of the light-transmissive hole 220 facing the first isolation opening 211 so that the mutual positional interference between the light-transmissive hole 220 and the first isolation opening 211 can be reduced.

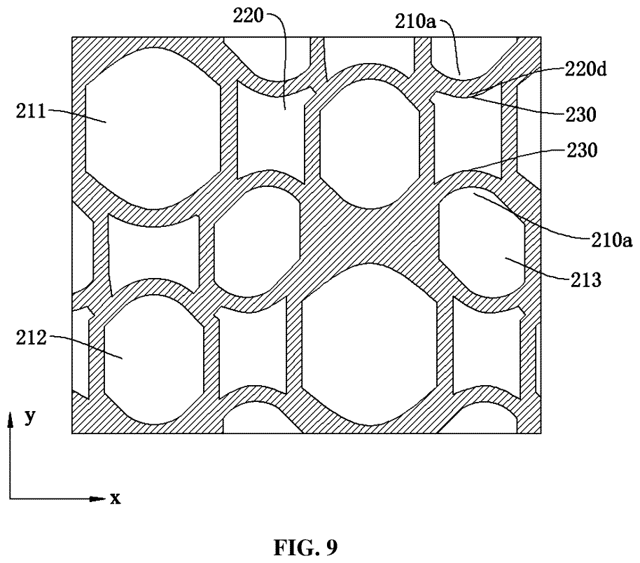

Optionally, as shown in FIG. 9, at least one light-transmissive hole 220 has at least two recessed portions 220d facing at least two isolation openings 210 located on the peripheral side of the at least one light-transmissive hole 220, and each of the at least two recessed portions 220d includes a first side edge 230. Multiple isolation openings 210 are provided around the peripheral side of the at least one light-transmissive hole 220, and at least two isolation openings 210 of the multiple isolation openings 210 have protruding portions 210a facing the same light-transmissive hole 220. Each of the protruding portions 210a includes a second side edge 240, and the shape of each second side edge 240 is adapted to the shape of a first side edge 230.

The at least one light-transmissive hole 220 has the at least two recessed portions 220d facing the at least two isolation openings 210 located on the peripheral side of the at least one light-transmissive hole 220, which refers to that the at least one light-transmissive hole 220 has the at least two recessed portions 220d, the at least two isolation openings 210 are provided on the peripheral side of the light-transmissive hole 220, and the recessed portions 220d are configured to correspond to the isolation openings 210.

In these optional embodiments, multiple isolation openings 210 may be provided on the peripheral side of the same light-transmissive hole 220. The same light-transmissive hole 220 is provided with multiple recessed portions 220d to be matched with the protruding portions 210a of at least two of the multiple isolation openings 210 on the peripheral side of the same light-transmissive hole 220. Thus, the shape of the light-transmissive hole 220 can be better adapted to the shape of each of the multiple isolation openings 210 on the peripheral side so that the distribution area of the light-transmissive hole 220 can be further increased and the transmittance is improved.

Optionally, as shown in FIG. 9, the light-transmissive hole 220 has two first side edges 230, two isolation openings 210 are provided around the same light-transmissive hole 220, and each of the two isolation openings 210 has second side edges 240. That is, one light-transmissive hole 220 may have two recessed portions 220d, and each recessed portion 220d has a first side edge 230. The two recessed portions 220d face the two isolation openings 210 one to one. Each of the two isolation openings 210 is provided with protruding portions 210a and the second side edges 240. Thus, the distribution area of the light-transmissive hole 220 can be further increased and the transmittance is improved.

Optionally, when the isolation opening 210 is elliptical as shown in FIG. 2, the light-transmissive hole 220 may have four first side edges 230. Four isolation openings 210 are provided around the same light-transmissive hole 220, and each of the four isolation openings 210 has a second side edge 240. That is, one light-transmissive hole 220 may have four recessed portions 220d, and each recessed portion 220d has a first side edge 230. The four recessed portions 220d face the four isolation openings 210 one to one. Each of the four isolation openings 210 is provided with a protruding portion 210a and the second side edge 240. Thus, the distribution area of the light-transmissive hole 220 can be further increased and the transmittance is improved.

Optionally, the first side edge 230 includes at least one of a straight line segment and a curved line segment. Thus, the shape of the light-transmissive hole 220 can be better adapted to the shape of each of the multiple isolation openings 210 on the peripheral side of the light-transmissive hole 220 so that the distribution area of the light-transmissive hole 220 can be further increased and the transmittance is improved.

In some optional embodiments, as shown in FIGS. 2 and 5, the isolation openings 210 include first isolation openings 211 and second isolation openings 212. The first isolation openings 211 and the second isolation openings 212 are alternately arranged along the first direction X to form a first opening group H1. First light-transmissive holes 221 and second light-transmissive holes 222 are alternately arranged along the first direction X so that the first light-transmissive hole 221 or the second light-transmissive hole 222 is provided between a first isolation opening 211 and a second isolation opening 212 which are adjacent to each other. At least one of the first light-transmissive hole 220 and the second light-transmissive hole 220 is provided with a recessed portion 220d.

In these optional embodiments, the first isolation openings 211 and the second isolation openings 212 are alternately arranged along the first direction X, and the first light-transmissive holes 221 and the second light-transmissive holes 222 are alternately arranged along the first direction X. Thus, the first light-transmissive hole 221 and the second light-transmissive hole 222 are provided on two sides of any first isolation opening 211 or any second isolation opening 212 so that the distribution area of the light-transmissive holes 220 can be increased and the transmittance of the display panel is improved.

The light-emitting units 400 may be configured in various manners. Optionally, the light-emitting units 400 may include a first light-emitting unit 401, a second light-emitting unit 402, and a third light-emitting unit 403 in different colors. The first light-emitting unit 400 may be configured to correspond to the first isolation opening 211, and the second light-emitting unit 400 may be configured to correspond to a second isolation opening 212. The isolation openings 210 may further include a third isolation opening 213, and the third light-emitting unit 403 may be configured to correspond to the third isolation opening 213.

In some optional embodiments, as shown in FIG. 2, the orthographic projection of the metal structure 110 on the substrate 120 is outside the orthographic projection of the first light-transmissive hole 221 on the substrate 120 and the orthographic projection of the second light-transmissive hole 222 on the substrate 120.

In these optional embodiments, the position where the metal structure 110 is disposed is entirely staggered from the first light-transmissive hole 221 and the second light-transmissive hole 222. Thus, the transmittance of the regions where the first light-transmissive hole 221 and the second light-transmissive hole 222 are located can be ensured, and the transmittance of the display panel is improved.

The metal structure 110 may include a conductive structure in the array substrate 100. For example, the metal structure 110 includes at least one of a gate G, a signal line, and a capacitor plate C. The position where at least one of the gate G, the signal line, and the capacitor plate C is disposed is entirely staggered from the first light-transmissive hole 221 and the second light-transmissive hole 222. Thus, the transmittance of the regions where the first light-transmissive hole 221 and the second light-transmissive hole 222 are located can be ensured, and the transmittance of the display panel is improved. The signal line may be at least one of a scan signal line and a power signal line.

Optionally, as described above, the display panel further includes the driver circuit T. The driver circuit T includes a metal oxide transistor and a low-temperature polysilicon transistor. The gate G includes a first gate disposed on the metal oxide transistor and a second gate disposed on the low-temperature polysilicon transistor. The metal structure 110 includes at least one of the first gate and the second gate.

In these optional embodiments, the driver circuit T includes different types of transistors, that is, the metal oxide transistor and the low-temperature polysilicon transistor. The gate G includes the first gate and the second gate which are located in the different types of transistors. The metal structure 110 includes at least one of the first gate and the second gate. In this manner, the position where at least one of the first gate and the second gate is disposed is entirely staggered from the first light-transmissive hole 221 and the second light-transmissive hole 222. Thus, the transmittance of the regions where the first light-transmissive hole 221 and the second light-transmissive hole 222 are located can be ensured, and the transmittance of the display panel is improved.

The metal oxide transistor may be an indium gallium zinc oxide transistor. Optionally, the driver circuit T may include a drive transistor and a switch transistor. One of the metal oxide transistor and the low-temperature polysilicon transistor is the drive transistor, and the other one of the metal oxide transistor and the low-temperature polysilicon transistor is the switch transistor. Thus, the position where the gate of at least one of the drive transistor and the switch transistor is disposed is entirely staggered from the first light-transmissive hole 221 and the second light-transmissive hole 222. Optionally, the driver circuit may further include a threshold compensation transistor, a reset transistor, a light emission control transistor, and the like. An orthographic projection of each of the gates of these different types of transistors on the substrate 120 may be entirely outside the orthographic projection of the first light-transmissive hole 221 on the substrate 120 and the orthographic projection of the second light-transmissive hole 222 on the substrate 120 so that the transmittance of the display panel is further improved.

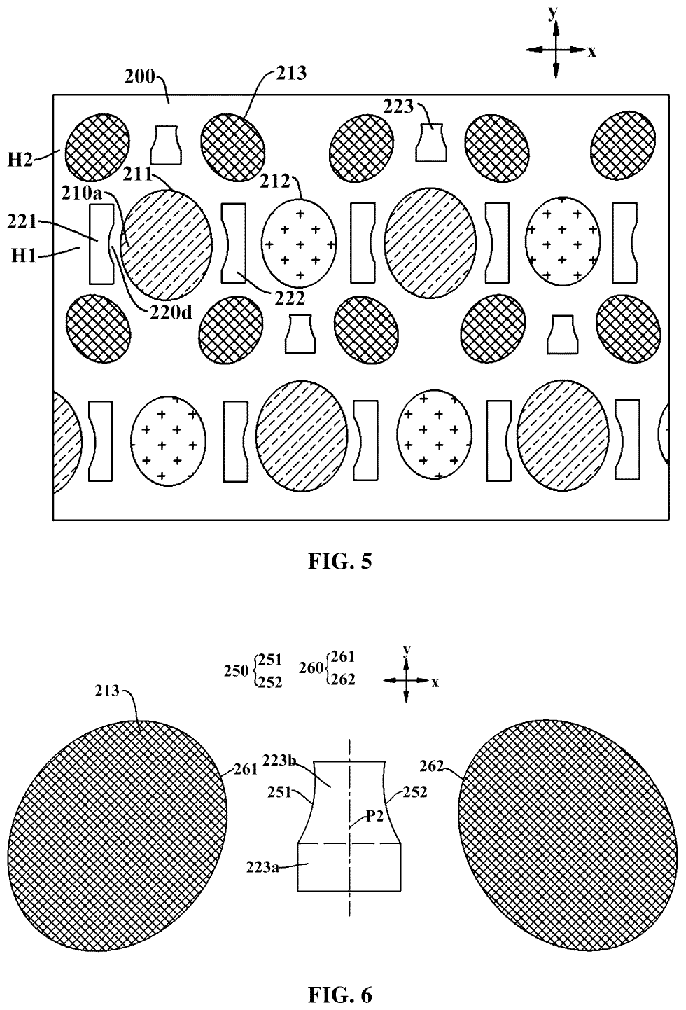

Referring to the preceding description, the isolation openings 210 may further include third isolation openings 213. Multiple third isolation openings 213 are arranged at intervals along the first direction X to form a second opening group H2. As shown in FIG. 6, the light-transmissive holes 220 further include third light-transmissive holes 223, and the third light-transmissive hole 223 is located between at least two adjacent third isolation openings 213. The third light-transmissive hole 223 located between two adjacent third isolation openings 213 in the second opening group H2 is added so that the total distribution area of the light-transmissive holes 220 can be further increased and the transmittance of the display panel is improved.

Optionally, an orthographic projection of the first isolation opening 211 on the array substrate 100 has a larger area than an orthographic projection of the second isolation opening 212 on the array substrate 100, and the orthographic projection of the second isolation opening 212 on the array substrate 100 has a larger area than an orthographic projection of the third isolation opening 213 on the array substrate 100. That is, the third isolation opening 213 for accommodating a blue light-emitting unit 400 has the largest distribution area. Thus, the distribution area of the blue light-emitting unit 400 can be increased and the service life of the blue light-emitting unit 400 is prolonged.

Optionally, two second isolation openings 212 and two first isolation openings 211 are provided on the peripheral side of the third isolation opening 213, and the two first isolation openings 211 and the two second isolation openings 212 are alternately arranged on the peripheral side of the third isolation opening 213. In this manner, two second light-emitting units 400 and two first light-emitting units 400 are disposed on the peripheral side of the third light-emitting unit 400, and the two first light-emitting units 400 and the two second light-emitting units 400 are alternately arranged on the peripheral side of the third light-emitting unit 400. Thus, the spacings between the third light-emitting unit 400 and the first and second light-emitting units 400 can be reduced, thereby improving the display effect of the display panel.

Optionally, an orthographic projection of the third light-transmissive hole 223 on the array substrate 100 has a smaller area than an orthographic projection of the first light-transmissive hole 221 on the array substrate 100 or an orthographic projection of the second light-transmissive hole 222 on the array substrate 100. Thus, the shape and dimension of the third light-transmissive hole 223 are better adapted to the third isolation openings 213.

In some optional embodiments, first opening groups H1 and second opening groups H2 are alternately arranged along the second direction Y, and the first opening groups H1 and the second opening groups H2 are staggered from each other. Thus, the first isolation opening 211 is correspondingly located between two third isolation openings 213 which are adjacent to each other along the first direction X, and at least one third light-transmissive hole 223 is located on a side of the first isolation opening 211 or the second isolation opening 212 in the second direction Y.

In these optional embodiments, the first opening groups H1 and the second opening groups H2 are alternately arranged along the second direction Y. In this manner, the first isolation opening 211 may be correspondingly located between the two adjacent third isolation openings 213, and the third light-transmissive hole 223 located between the two adjacent third isolation openings 213 may be located on the side of the first isolation opening 211 or the second isolation opening 212 in the second direction Y. Thus, the isolation openings 210 and the light-transmissive holes 220 are distributed more scientifically and reasonably, and the multiple light-transmissive holes 220 are distributed more evenly.

Optionally, at least one second isolation opening 212 is correspondingly located between two third isolation openings 213 which are adjacent to each other along the first direction X, and at least one third light-transmissive hole 223 is located on a side of the second isolation opening 212 in the second direction Y.

In these optional embodiments, the first light-transmissive hole 221, the second light-transmissive hole 222, and the third light-transmissive hole 223 are also provided on the peripheral side of the second isolation opening 212. Thus, the distribution area of the light-transmissive holes 220 can be further increased, and the light-transmissive holes 220 are distributed more evenly.

Optionally, a third light-transmissive hole 223 is provided on a side of each third isolation opening 213 in the second direction Y. Thus, the distribution area of the light-transmissive holes 220 can be further increased. For example, the third light-transmissive hole 223 is provided on one side of one of the third isolation openings 213 in the second direction Y, and no third light-transmissive hole 223 is provided on the other side of the third isolation opening 213 in a second direction. In this manner, among two groups of two adjacent third isolation openings 213, the third light-transmissive hole 223 is provided between one group of adjacent third isolation openings 213, and no third light-transmissive hole 223 is provided between the other group of adjacent third isolation openings 213.

Optionally, for the first isolation opening 211 and the second isolation opening 212 which are adjacent to each other, a third light-transmissive hole 223 is provided on one side of the first isolation opening 211 in the second direction Y, and a third light-transmissive hole 223 is provided on the opposite side of the second isolation opening 212 in the second direction Y so that the third light-transmissive holes 223 are distributed more evenly.

In some optional embodiments, the second opening group H2 further includes first gaps Q and second gaps Q2, where the first gap Q is located between two adjacent third isolation openings 213, and the second gap Q2 is located between two adjacent third isolation openings 213. The first gaps Q and the second gaps Q2 are alternately arranged along the first direction X, and the third light-transmissive hole 223 is located in the first gap Q.

In these optional embodiments, the third light-transmissive hole 223 is provided in the first gap Q while no third light-transmissive hole 223 is provided in a second gap Q2. The metal structure 110 can be avoided, and the influence of ambient light on the metal structure 110 correspondingly located in the second gap Q2 can be reduced.

Optionally, conductive wires are further disposed on the substrate 120. The wiring density of conductive wires in the region where the first gap Q is located is lower than the wiring density of conductive wires in the region where the second gap Q2 is located. The third light-transmissive hole 223 is provided in the first gap Q with the lower wiring density. Thus, the transmittance can be improved, and the influence of ambient light on the conductive wires can be reduced.

Optionally, as shown in FIG. 6, an orthographic projection of at least one of the conductive wires on the substrate 120 at least partially overlaps an orthographic projection of the third light-transmissive hole 223 on the substrate 120. That is, the conductive wire may be correspondingly disposed in the third light-transmissive hole 223. For example, the conductive wire passes through the center of the third light-transmissive hole 223. Thus, the transmittance can be improved, and the configuration manner of the third light-transmissive hole 223 can be simplified.

Optionally, the conductive wire includes a power signal line. An orthographic projection of the power signal line on the substrate 120 at least partially overlaps an orthographic projection of the third light-transmissive hole 223 on the substrate 120. Optionally, the power signal line includes at least one of a drive power voltage signal line VDD and a voltage reference signal line.

The shape of the orthographic projection of the third light-transmissive hole 223 on the array substrate 100 may be configured in various manners. For example, the orthographic projection of the third light-transmissive hole 223 on the array substrate 100 may be polygonal, circular, or elliptical.

Optionally, as shown in FIGS. 6 to 8, the shape of the third light-transmissive hole 223 is adapted to the shapes of the third isolation openings 213 on two sides of the third light-transmissive hole 223. For example, in some optional embodiments, the third light-transmissive hole 223 includes third side edges 250 facing the third isolation openings 213. The third isolation openings 213 have fourth side edges 260 facing the third side edges 250. The third side edges 250 and the fourth side edge 260 are equally spaced.

The third side edge 250 and the fourth side edge 260 are equally spaced, which does not refer to that the third side edge 250 and the fourth side edge 260 are equally spaced strictly in mathematical and geometric senses. Instead, the third side edge 250 and the fourth side edge 260 are equally spaced within a preparation process error range.

In these optional embodiments, the third side edge 250 and the fourth side edge 260 are equally spaced so that the shape of the third light-transmissive hole 223 is better adapted to the shapes of the third isolation openings 213. Thus, the distribution area of the third light-transmissive hole 223 can be increased as much as possible, and the transmittance of the display panel is improved. Moreover, the third side edge 250 and the fourth side edge 260 are equally spaced so that it is ensured that the third light-transmissive hole 223 has a sufficiently large distribution area and the mutual interference and influence between the third light-transmissive hole 223 and the third isolation openings 213 can be reduced.

Optionally, the third side edge 250 and the fourth side edge 260 may be arc-shaped.

Optionally, the third side edges 250 include a fifth sub-edge 251 and a sixth sub-edge 252 located on the two sides of the third light-transmissive hole 223 in the first direction X, and the fourth side edges 260 include a seventh sub-edge 261 facing the fifth sub-edge 251 and an eighth sub-edge 262 facing the sixth sub-edge 252. The seventh sub-edge 261 and the eighth sub-edge 262 are located on the two adjacent third isolation openings 213. The fifth sub-edge 251 and the seventh sub-edge 261 are equally spaced, and the sixth sub-edge 252 and the eighth sub-edge 262 are equally spaced.

Optionally, the third light-transmissive hole 223 has a second median line P2 extending along the second direction Y, and the fifth sub-edge 251 and the sixth sub-edge 252 are symmetrically disposed with respect to the second median line P2.

In these optional embodiments, the distances from edges of the third light-transmissive hole 223 facing the third isolation openings 213 on the two sides of the third light-transmissive hole 223 to edges of the third isolation openings 213 are equal to each other. Thus, the shape of the third light-transmissive hole 223 is better adapted to the shapes of the third isolation openings 213 on the two sides of the third light-transmissive hole 223.

Optionally, the third light-transmissive hole 223 has the second median line P2 extending along the second direction Y, and the fifth sub-edge 251 and the sixth sub-edge 252 are symmetrically disposed with respect to the second median line P2. Optionally, the second median line P2 passes the center of the third light-transmissive hole 223 in the first direction X and is formed by extending along the second direction Y. The fifth sub-edge 251 and the sixth sub-edge 252 are symmetrical with respect to the second median line P2 so that the shape of the third light-transmissive hole 223 can be simplified, thereby facilitating the preparation and formation of the third light-transmissive hole 223.

In some optional embodiments, the third light-transmissive hole 223 includes a first segment 223a and a second segment 223b which are sequentially distributed along the second direction Y. The third side edges 250 are disposed at the second segment 223b. The width of the first segment 223a in the first direction X is greater than or equal to the width of the second segment 223b in the first direction X.

In these optional embodiments, the third light-transmissive hole 223 is configured to have the first segment 223a and the second segment 223b which have different widths. Thus, the shape of the third light-transmissive hole 223 is better adapted to the shape of the gap between the two adjacent third isolation openings 213 so that the distribution area of the third light-transmissive hole 223 can be appropriately increased.

For example, the two third isolation openings 213 on the two sides of the third light-transmissive hole 223 in the first direction X are elliptical. In addition, along the direction from the first segment 223a to the second segment 223b, the two third isolation openings 213 are inclined towards each other. As a result, the width of the gap where the first segment 223a is located is greater than the width of the gap where the second segment 223b is located. Therefore, the first segment 223a is configured to be wider so that the distribution area of the third light-transmissive hole 223 can be appropriately increased, and it is less prone to cause the mutual influence between the third light-transmissive hole 223 and the third isolation openings 213. For example, the third isolation openings 213 are elliptical. The two third isolation openings 213 are inclined towards each other, which may be understood as follows: the straight lines where the major axes of the two third isolation openings 213 are located intersect with each other.

Optionally, the first segment 223a is rectangular and is configured to have a constant width in the second direction Y. Thus, the shape of the first segment 223a and the shape of the third light-transmissive hole 223 can be simplified, thereby facilitating the preparation and formation of the third light-transmissive hole 223.

Preferably, along a direction away from the first segment 223a, the width of the second segment 223b in the first direction X gradually decreases. Thus, the shape of the second segment 223b is better adapted to the shape of the gap where the second segment 223b is located.

Optionally, the second segment 223b has a fourth straight edge 223b1 connected between the fifth sub-edge 251 and the sixth sub-edge 252. The second median line P2 passes the midpoint of the fourth straight edge 223b1 in the first direction X. The fourth straight edge 223b1 extends linearly along the first direction X so that the shape of the second segment 223b and the shape of the third light-transmissive hole 223 are simplified, thereby facilitating the preparation and formation of the third light-transmissive hole 223.

In some optional embodiments, for the first light-transmissive hole 221 and a first isolation opening 211 and a second isolation opening 212 which are located on two sides of the first light-transmissive hole 221, the distance from the first isolation opening 211 to the first light-transmissive hole 221 is not equal to the distance from the second isolation opening 212 to the first light-transmissive hole 221. That is, the first isolation opening 211 and the second isolation opening 212 are not symmetrically provided with respect to the first light-transmissive hole 221. Thus, the first light-transmissive hole 221 can be provided in a region with a relatively low density of metal structures 110 so that the transmittance is ensured.

In some optional embodiments, for the second light-transmissive hole 222 and a first isolation opening 211 and a second isolation opening 212 which are located on two sides of the second light-transmissive hole 222, the distance from the first isolation opening 211 to the second light-transmissive hole 222 is not equal to the distance from the second isolation opening 212 to the second light-transmissive hole 222. That is, the first isolation opening 211 and the second isolation opening 212 are not symmetrically provided with respect to the second light-transmissive hole 222. Thus, the second light-transmissive hole 222 can be provided in a region with a relatively low density of metal structures 110 so that the transmittance is ensured.

In some optional embodiments, for the first isolation opening 211 and a first light-transmissive hole 221 and a second light-transmissive hole 222 which are located on two sides of the first isolation opening 211, the distance from the first light-transmissive hole 221 to the first isolation opening 211 is not equal to the distance from the second light-transmissive hole 222 to the first isolation opening 211. That is, the first light-transmissive hole 221 and the second light-transmissive hole 222 are not symmetrically provided with respect to the first isolation opening 211. Thus, the first light-transmissive hole 221 and the second light-transmissive hole 222 can be provided in regions with relatively low densities of metal structures 110 so that the transmittance is ensured.

In some optional embodiments, for the second isolation opening 212 and a first light-transmissive hole 221 and a second light-transmissive hole 222 which are located on two sides of the second isolation opening 212, the distance from the first light-transmissive hole 221 to the second isolation opening 212 is not equal to the distance from the second light-transmissive hole 222 to the second isolation opening 212. That is, the first light-transmissive hole 221 and the second light-transmissive hole 222 are not symmetrically provided with respect to the second isolation opening 212. Thus, the first light-transmissive hole 221 and the second light-transmissive hole 222 can be provided in regions with relatively low densities of metal structures 110 so that the transmittance is ensured.

In some optional embodiments, the orthographic projection of the first light-transmissive hole 220 on the substrate 120 has a larger area than the orthographic projection of the second light-transmissive hole 220 on the substrate 120. The first light-transmissive hole 221 and the second light-transmissive hole 222 with different areas are provided so that the light-transmissive holes 220 can be better adapted to gaps of different dimensions. Thus, the overall distribution area of the light-transmissive holes 220 can be further increased.

In other optional embodiments, the first light-transmissive hole 221 and the second light-transmissive hole 222 are located on two sides of the same isolation opening 210 in the first direction X. Thus, the first light-transmissive hole 221 and the second light-transmissive hole 222 are spaced apart along the first direction X so that the arrangement structure of the light-transmissive holes 220 can be simplified.

Optionally, referring to FIGS. 2 and 7, the first light-transmissive hole 221 and the second light-transmissive hole 222 have the same length in the second direction Y, so that the shape of the first light-transmissive hole 221 and the shape of the second light-transmissive hole 222 are simplified, facilitating the preparation and formation of the first light-transmissive hole 221 and the second light-transmissive hole 222. For example, the length of the first light-transmissive hole 221 in the second direction Y is b1, and the length of the second light-transmissive hole 222 in the second direction Y is b2, where b1 and b2 are equal.

Optionally, the width of at least part of the first light-transmissive hole 221 in the first direction X is greater than the width of the second light-transmissive hole 222 in the first direction X. Thus, the first light-transmissive hole 221 and the second light-transmissive hole 222 have different distribution areas. In addition, the adaptation of the shape of the first light-transmissive hole 221 and the shape of the second light-transmissive hole 222 to the distribution patterns of the metal structures 110 in the array substrate 100 is facilitated. For example, the minimum width of the first light-transmissive hole 221 in the first direction X is W1, and the minimum width of the second light-transmissive hole 222 in the first direction X is W2, where W1 is greater than W2.

The shape of the first light-transmissive hole 221 and the shape of the second light-transmissive hole 222 may be configured in various manners. For example, the first light-transmissive holes 221 and the second light-transmissive hole 222 may be polygonal, circular, elliptical, or special-shaped.

As described above, as shown in FIG. 3, the display panel further includes a first encapsulation layer 500. The first encapsulation layer 500 includes encapsulation portions 510 which are spaced apart from each other to encapsulate the isolation openings 210. An avoidance gap is formed between adjacent encapsulation portions 510. An orthographic projection of the avoidance gap on the substrate 120 at least partially overlaps an orthographic projection of the light-transmissive hole 220 on the substrate 120.

The encapsulation portion 510 is configured to encapsulate an isolation opening 210, that is, the encapsulation portion 510 is configured to encapsulate at least part of the light-emitting unit 400 in the isolation opening 210. The encapsulation portion 510 may extend from the isolation opening 210 to a side of the isolation structure 200 facing away from the substrate.

In these optional embodiments, the orthographic projection of the avoidance gap on the substrate 120 at least partially overlaps the orthographic projection of the light-transmissive hole 220 on the substrate 120. That is, the light-transmissive hole 220 and the encapsulation portion 510 are at least partially staggered from each other so that the transmittance of the region where the light-transmissive hole 220 is located can be improved.

Optionally, the orthographic projection of the light-transmissive hole 220 on the substrate 120 is within the orthographic projection of the avoidance gap on the substrate 120. That is, the light-transmissive hole 220 and the encapsulation portion 510 are entirely staggered from each other so that the transmittance of the region where the light-transmissive hole 220 is located is further improved.

Optionally, the material of the first encapsulation layer 500 may include an inorganic material so that the first encapsulation layer 500 has good compactness.

Optionally, as shown in FIG. 4, the encapsulation layer further includes a second encapsulation layer 600 located on a side of the first encapsulation layer 500 facing away from the array substrate 100. The material of the second encapsulation layer 600 may include an organic material.

Optionally, the encapsulation layer further includes a third encapsulation layer 700 located on a side of the second encapsulation layer 600 facing away from the array substrate 100. The material of the third encapsulation layer 700 may be the same as the material of the first encapsulation layer 500. For example, the third encapsulation layer 700 may be made of an inorganic material.

Optionally, when the pixel defining layer 300 includes the pixel defining portions 310 and the pixel openings 320 and the pixel opening 320 communicates with the isolation opening 210, an orthographic projection of the light-transmissive hole 220 on the substrate 120 is within an orthographic projection of the pixel defining portion 310 on the substrate 120. That is, the pixel defining portion 310 is not provided with any through hole to correspond to the light-transmissive hole 220. Thus, the configuration manner of the pixel defining portion 310 can be simplified.

Optionally, the pixel defining portion 310 is in contact with and connected to the second encapsulation layer 600 in the light-transmissive hole 220. Thus, the problem is alleviated that the encapsulation layer is prone to peel off.

Optionally, the display panel further includes a planarization layer and a buffer layer which are sequentially disposed on a side of the pixel defining layer facing the substrate 120. Orthographic projections of the light-transmissive holes 220 on the substrate 120 are within an orthographic projection of at least one of the buffer layer or the planarization layer on the substrate 120. In the regions where the light-transmissive holes 220 are located, the buffer layer and the planarization layer are provided with no hole so that the buffer layer and the planarization layer can better support films such as the isolation structure 200.

The light-emitting units 400 may be arranged in various manners. For example, multiple light-emitting units 400 are arranged in an array along the first direction X and the second direction Y in a display region of the display panel. The multiple isolation openings 210 are distributed in an array along the first direction X and the second direction Y. The first light-transmissive hole 221 and the second light-transmissive hole 222 may be located on the peripheral side of the isolation opening 210. For example, the first light-transmissive hole 221 is located on a side of the isolation opening 210 in the first direction X, and the second light-transmissive hole 222 is located on a side of the isolation opening 210 in the second direction Y.

In some optional embodiments, the minimum spacing between the light-transmissive hole 220 and the isolation opening 210 is 3 μm to 4 μm. That is, the minimum spacing between the edge of the orthographic projection of the light-transmissive hole 220 on the array substrate 100 and the edge of the orthographic projection of the isolation opening 210 on the array substrate 100 is 3 μm to 4 μm. This configuration aims to alleviate the problem that an excessively large spacing between the light-transmissive hole 220 and the isolation opening 210 influences the distribution area of the light-transmissive hole 220 and the transmittance of the display panel. In addition, the problem can be also alleviated that an excessively small spacing between the light-transmissive hole 220 and the isolation opening 210 increases process difficulties and causes the mutual influence between the light-transmissive hole 220 and the isolation opening 210.

Optionally, the minimum spacing between the first light-transmissive hole 221 and any one of the first isolation opening 211, the second isolation opening 212, and the third isolation opening 213 is 3 μm to 4 μm. The minimum spacing between the second light-transmissive hole 222 and any one of the first isolation opening 211, the second isolation opening 212, and the third isolation opening 213 is 3 μm to 4 μm. The minimum spacing between the third light-transmissive hole 223 and any one of the first isolation opening 211, the second isolation opening 212, and the third isolation opening 213 is 3 μm to 4 μm.

In any one of the preceding embodiments, the display panel includes a display region. The display region includes a main display region AA2 and a light-transmissive display region AA1. The light-transmissive holes 220 are located in the light-transmissive display region AA1 so that the transmittance of the light-transmissive display region AA1 is improved, thereby facilitating the under-screen integration of the photosensitive module in the light-transmissive display region AA1.

As shown in FIGS. 1 to 9, a display panel is further provided in a first aspect of the present application. The display panel includes an array substrate 11 and an isolation structure 200. The array substrate 11 includes a substrate 120 and a metal structure 110 disposed on the substrate 120. The isolation structure 200 is disposed on a side of the array substrate 11. The isolation structure 200 encloses and forms isolation openings 210 and light-transmissive holes 220. An orthographic projection of a light-transmissive hole 220 on the substrate 120 is at least partially staggered from an orthographic projection of the metal structure 110 on the substrate 120. The isolation openings 210 is configured to accommodate at least part of a light-emitting unit 400. The light-transmissive holes 220 include a first light-transmissive hole 221 and a second light-transmissive hole 222. The first light-transmissive hole 221 and the second light-transmissive hole 222 are located on the peripheral side of the same isolation opening 210, and the shape of an orthographic projection of the first light-transmissive hole 221 on the substrate 120 is different from the shape of an orthographic projection of the second light-transmissive hole 222 on the substrate 120.

In the embodiment of the present application, the first light-transmissive hole 221 and the second light-transmissive hole 222 which have different shapes are provided. Thus, the different light-transmissive holes 220 are adaptable to the regions where they are located so that the overall distribution area of the light-transmissive holes 220 can be increased as much as possible, thereby increasing transmittance.

The display panel in the embodiment of the present application may be cross-referenced with the display panel in any one of the preceding embodiments. The display panel in the embodiment of the present application has the same structures as the display panel in any one of the preceding embodiments, and the same structures are not described again. For example, the display panel in the embodiment of the present application may include structures such as the recessed portion 220d and the protruding portion 210a mentioned above.

As shown in FIGS. 1 to 9, a display panel is further provided in the first aspect of the present application. The display panel includes an array substrate 11, an isolation structure 200, and light-emitting units 400. The array substrate 11 includes a substrate 120 and a first active layer 130 disposed on the substrate 120. The isolation structure 200 is disposed on a side of the array substrate 11. The isolation structure 200 encloses and forms multiple isolation openings 210 and multiple light-transmissive holes 220. An orthographic projection of a light-transmissive hole 220 on the substrate 120 is at least partially staggered from an orthographic projection of the first active layer 130 on the substrate 120. The light-emitting units 400 are configured to correspond to the isolation openings 210. The preceding display panel 1 provided in the present application includes the array substrate 11, the light-emitting units 400, and the isolation structure 200. The light-emitting units 400 are configured to emit light to implement the display function of the display panel 1. The isolation structure 200 encloses and forms the isolation openings 210 and the light-transmissive holes 220. The isolation openings 210 are configured to expose the light-emitting units 400 to implement light emission. The light-transmissive holes 220 are configured to implement light transmission of the display panel 1 to improve the transmittance of the display panel 1. The orthographic projection of the light-transmissive hole 220 on the substrate 120 is at least partially staggered from the orthographic projection of the first active layer 130 on the substrate 120. Thus, the influence of natural light in the light-transmissive hole 220 on the first active layer 130 can be reduced, thereby improving the performance of the first active layer 130 and improving the use performance of the display panel.

Optionally, as shown in FIGS. 3 and 8, the first active layer 130 includes a first channel region 131. The orthographic projection of the light-transmissive hole 220 on the substrate 120 is staggered from an orthographic projection of the first channel region 131 on the substrate 120. That is, the first channel region 131 and the light-transmissive hole 220 are staggered from each other. Thus, the amount of light entering the first channel region 131 through the light-transmissive hole 220 can be reduced or even eliminated. The influence of photo-generated carriers on the first channel region 131 is reduced, thereby improving the performance of the first channel region 131 and improving the use performance of the display panel.

The material of the first active layer 130 may be configured in various manners. Optionally, the material of the first active layer 130 includes a metal oxide semiconductor material, for example, an indium gallium zinc oxide semiconductor material. Optionally, referring to the preceding description, when a driver circuit T includes a metal oxide transistor and a low-temperature polysilicon transistor, at least part of the first active layer 130 may be used as a semiconductor portion of the metal oxide transistor.

In some optional embodiments, as shown in FIGS. 3 and 8, the display panel further includes a second active layer 140. An orthographic projection of the second active layer 140 on the substrate 120 is at least partially staggered from the orthographic projection of the light-transmissive hole 220 on the substrate 120. Thus, the influence of natural light in the light-transmissive hole 220 on the second active layer 140 can be reduced, thereby improving the performance of the second active layer 140 and improving the use performance of the display panel.

Optionally, as shown in FIG. 3, the second active layer 140 includes a second channel region 141. An orthographic projection of the second channel region 141 on the substrate 120 is at least partially staggered from the orthographic projection of the light-transmissive hole 220 on the substrate 120. That is, the second channel region 141 and the light-transmissive hole 220 are staggered from each other. Thus, the amount of light entering the second channel region 141 through the light-transmissive hole 220 can be reduced or even eliminated. The influence of photo-generated carriers on the second channel region 141 is reduced, thereby improving the performance of the second channel region 141 and improving the use performance of the display panel.

Alternatively, as shown in FIG. 8, a light-shielding layer 150 is disposed between the second channel region 141 and the isolation structure 200. An orthographic projection of the second channel region 141 on the substrate is within an orthographic projection of the light-shielding layer 150 on the substrate. Due to the existence of the light-shielding layer 150, the amount of light entering the second channel region 141 through the light-transmissive hole 220 can be reduced or even eliminated. The influence of photo-generated carriers on the second channel region 141 is reduced, thereby improving the performance of the second channel region 141 and improving the use performance of the display panel.

The light-shielding layer 150 may be disposed at various positions and may be disposed in the same layer as a capacitor plate, a gate, a signal line, or the like. Optionally, the material of the light-shielding layer 150 may include a metal light-shielding material so that the light-shielding layer 150 has good light-shielding performance.

Optionally, the material of the second active layer 140 includes a low-temperature polycrystalline silicon semiconductor material. When the driver circuit T includes the metal oxide transistor and the low-temperature polysilicon transistor, at least part of the second active layer 140 may be used as a semiconductor portion of the low-temperature polysilicon transistor.

Optionally, the first active layer 130 and the second active layer 140 are disposed in different layers and may be prepared with different materials.

Optionally, the first active layer 130 is located on a side of the second active layer 140 facing away from the substrate 120. It is convenient to prepare the second active layer 140 before the preparation of the first active layer 130. Thus, the influence of the preparation of the second active layer 140 on the first active layer 130 can be reduced.

Optionally, the display panel in the embodiment of the present application may be cross-referenced with the display panel in any one of the preceding embodiments. The display panel in the embodiment of the present application has the same structures and features as the display panel in any one of the preceding embodiments, and the same structures and features are not described again.

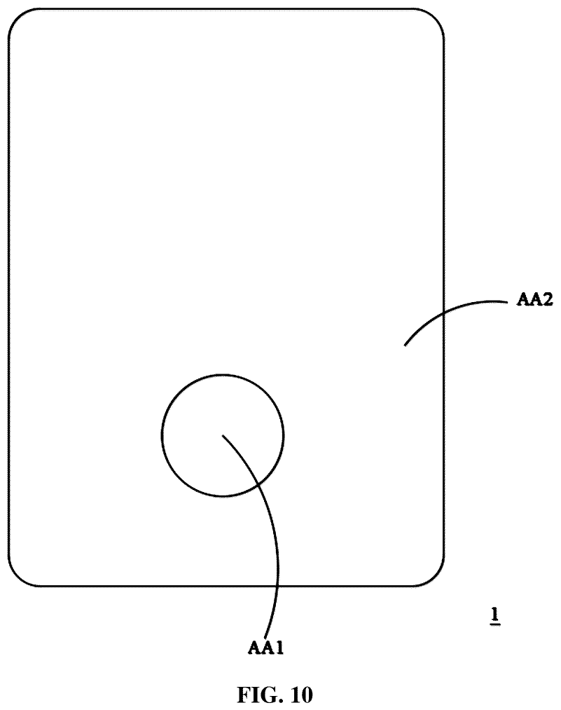

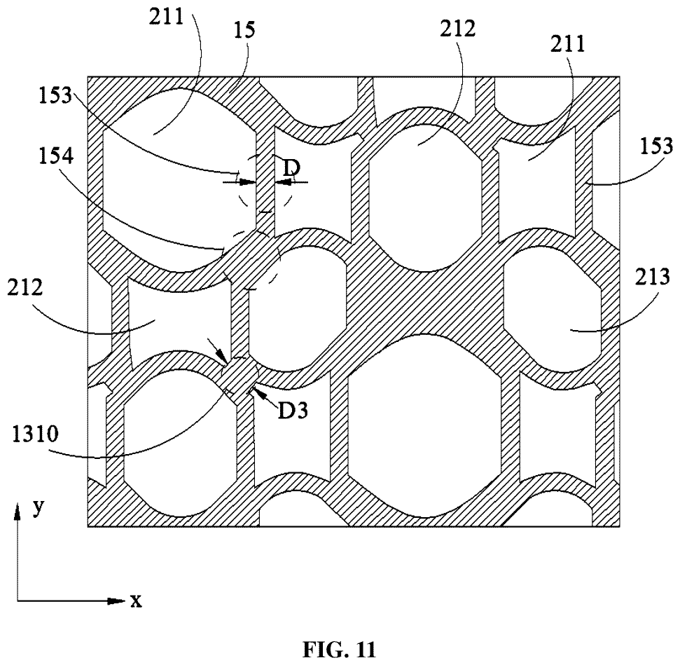

As shown in FIGS. 10 to 16, a display panel is further provided in the first aspect of the present application. The display panel includes an array substrate 11, a light-emitting layer 40, and an isolation structure 200. The light-emitting layer 40 is located on a side of the array substrate 11 and includes multiple light-emitting units 400. At least part of the isolation structure 200 encloses and forms isolation openings 210 and light-transmissive holes 220. The isolation openings 210 are configured to expose the light-emitting units 400. The light-transmissive holes 220 are formed between at least part of the isolation openings 210, where the at least part of the isolation openings 210 are adjacent to each other. The isolation structure 200 includes first constant-width segments 153 surrounding a light-transmissive hole 220. At least an orthographic projection of the first constant-width segment 153 on the array substrate 11 is between an orthographic projection of a light-transmissive hole 220 on the array substrate 11 and an orthographic projection of an isolation opening 210 on the array substrate 11. The first constant-width segment 153 is configured to have a constant width. The width direction of the first constant-width segment 153 refers to the direction in which one of the orthographic projection of the light-transmissive hole 220 on the array substrate 11 and the orthographic projection of the isolation opening 210 on the array substrate 11 points towards the other.

Optionally, the array substrate 11 and the substrate in patent application No. 202410382548.0, whose priority the present application claims, may be the same structure of the display panel. The isolation opening 210 and the opening portion in patent application No. 202410382548.0, whose priority the present application claims, may be the same structure.

The preceding display panel 1 provided in the present application includes the array substrate 11, the light-emitting layer 40, and the isolation structure 200. The light-emitting layer 40 includes the multiple light-emitting units 400. The light-emitting units 400 are configured to emit light to implement the display function of the display panel 1. The isolation structure 200 encloses and forms the isolation openings 210 and the light-transmissive holes 220. The isolation openings 210 are configured to expose the light-emitting units 400 to implement light emission. The light-transmissive hole 220 is located between at least part of the isolation openings 210, where the at least part of the isolation openings 210 are adjacent to each other. That is, the orthographic projection of the light-transmissive hole 220 on the array substrate 11 is between orthographic projections of at least part of the light-emitting units 400 on the array substrate 11. Thus, light transmission is implemented in the region between adjacent light-emitting units 400 so that the transmittance of the display panel 1 is improved. The isolation structure 200 includes the first constant-width segments 153 surrounding the light-transmissive hole 220. The first constant-width segment 153 is located between the light-transmissive hole 220 and the isolation opening 210. The first constant-width segment 153 is configured to have the constant width. That is, the part of the isolation structure 200 between the light-transmissive hole 220 and the isolation opening 210 is configured to have the constant width. On the premise that it can be ensured that the area of the isolation opening 210 remains constant and a preparation yield is ensured, the area of the light-transmissive hole 220 is increased as much as possible, thereby increasing the distribution area of the light-transmissive hole 220 and improving the transmittance of the display panel 1.

Optionally, the opening shape of the light-transmissive hole 220 may be reasonably configured. For example, the shape of the light-transmissive hole 220 is adapted to the shape of the isolation opening 210, and the light-transmissive hole 220 is caused to be special-shaped. Thus, the first constant-width segment 153 can be configured to have the constant width so that the area of the light-transmissive hole 220 is increased as much as possible.

In addition, the first constant-width segment 153 is configured to have the constant width so that the amount of light reflected at different positions on the first constant-width segment 153 tends to be consistent. Thus, the display effect of the display panel 1 can be improved. The width direction of the first constant-width segment 153 refers to the direction in which one of orthographic projections of the light-transmissive hole 220 and the isolation opening 210 on two sides of the first constant-width segment 153 on the array substrate 11 points towards the other. For example, the width direction of the first constant-width segment 153 may refer to the direction in which the geometric center of one of the orthographic projections of the light-transmissive hole 220 and the isolation opening 210 on the two sides of the first constant-width segment 153 on the array substrate 11 points towards the geometric center of the other.

In the preceding embodiment, as shown in FIG. 10, the display panel 1 may be a transparent display panel. Alternatively, the display panel 1 may include a first display region AA1 and a second display region AA2. The first display region AA1 is provided with the preceding light-transmissive holes 220 so that the transmittance of the first display region AA1 is greater than the transmittance of the second display region AA2. Optionally, the preceding first constant-width segments 153 are disposed in the first display region AA1 so that the distribution area of the light-transmissive holes 220 is increased. A photosensitive module such as a camera module or a fingerprint recognition module may be disposed under the first display region AA1. The first display region AA1 has relatively high transmittance and can improve the performance of the photosensitive module, thereby improving the performance of the display panel 1.

In some optional embodiments, as shown in FIGS. 10 to 14, the isolation structure 200 includes a first sub-layer 201 and a second sub-layer 202. The first sub-layer 201 is located on a side of the second sub-layer 202 facing the array substrate 11. An orthographic projection of the first sub-layer 201 on the array substrate 11 is within an orthographic projection of the second sub-layer 202 on the array substrate 11.

In these optional embodiments, the isolation structure 200 includes the first sub-layer 201 and the second sub-layer 202. The second sub-layer 202 is located on a side of the first sub-layer 201 facing away from the array substrate 11. The orthographic projection of the first sub-layer 201 on the array substrate 11 is within the orthographic projection of the second sub-layer 202 on the array substrate 11. That is, the orthographic projection of the first sub-layer 201 has a smaller area than the orthographic projection of the second sub-layer 202 so that recesses can be formed under the second sub-layer 202. When the light-emitting units 400 are subsequently prepared, a light-emitting material can be disconnected at edges of the second sub-layer 202 to form the light-emitting units 400 which are independent of each other. Thus, the process for preparing a fine mask can be omitted, thereby simplifying the preparation process of the display panel 1.

When the isolation structure 200 includes the first sub-layer 201 and the second sub-layer 202, the first constant-width segment 153 may be disposed in the first sub-layer 201 or the second sub-layer 202. Optionally, the first constant-width segment 153 may be disposed in the second sub-layer 202. For example, the first constant-width segment 153 includes a second sub-segment 202a disposed in the second sub-layer 202.

In these optional embodiments, the second sub-layer 202 has a relatively large dimension, and the shape and dimension of the second sub-layer 202 determine the shape and dimension of the light-transmissive hole 220. Therefore, the second sub-segment is disposed in the second sub-layer 202 so that it can be ensured that the dimension of the light-transmissive hole 220 can be sufficiently large. Thus, the distribution area of the light-transmissive hole 220 can be increased.

Optionally, the first constant-width segment 153 further includes a first sub-segment 201a disposed in the first sub-layer 201. That is, the constant-width segment is also disposed in the first sub-layer 201 so that the shape of the first sub-layer 201 is better adapted to the shape of the second sub-layer 202, thereby ensuring the performance of the isolation structure 200.

In a possible embodiment, along a direction parallel to the plane where the array substrate 11 is located, the width D of the first constant-width segment 153 is 1 μm to 4 μm. For example, the width D of the first constant-width segment 153 is 1 μm, 1.1 μm, 1.5 μm, 1.8 μm, 2 μm, 2.3 μm, 2.7 μm, 2.9 μm, 3 μm, 3.2 μm, or 4 μm. That is, the width D of an orthographic projection of the first constant-width segment 153 on the array substrate 11 is 1 μm to 4 μm. Thus, the problem can be alleviated that an excessively narrow first constant-width segment 153 causes preparation processes to be excessively difficult, influencing the preparation of the display panel 1. In addition, the problem can be alleviated that an excessively wide first constant-width segment 153 influences the distribution area of the light-transmissive hole 220, influencing the transmittance of the display panel 1.

Optionally, when the isolation structure 200 includes the first sub-layer 201 and the second sub-layer 202, along the direction parallel to the plane where the array substrate 11 is located, the width of the first sub-segment 201a is a first preset dimension D1. The first preset dimension D1 is 1 μm to 3 μm. For example, the first preset dimension D1 is 1 μm, 1.1 μm, 1.5 μm, 1.8 μm, 2 μm, 2.3 μm, 2.7 μm, 2.9 μm, or 3 μm, etc.

Optionally, along the direction parallel to the plane where the array substrate 11 is located, the width of the second sub-segment 202a is a second preset dimension D2. The second preset dimension D2 is 2 μm to 4 μm. For example, the second preset dimension D2 is 2 μm, 2.3 μm, 2.7 μm, 2.9 μm, 3 μm, 3.2 μm, or 4 μm, etc.

In these optional embodiments, the first sub-segment 201a is relatively narrow while the second sub-segment 202a is relatively wide. On the premise that it is ensured that the orthographic projection of the first sub-layer 201 on the array substrate 11 is within the orthographic projection of the second sub-layer 202 on the array substrate 11, the width of the second sub-segment 202a is minimized so that the distribution area of the light-transmissive hole 220 is ensured.

The light-emitting units 400 may be configured in various manners. For example, the light-emitting unit 400 includes a first electrode 410, a light-emitting layer 420, and a second electrode 430 which are stacked along a direction away from the array substrate 11. The material of the isolation structure 200 may include a conductive material so that the second electrode 430 can be electrically connected to the isolation structure 200. Thus, the second electrodes 430 of multiple light-emitting units 400 are arranged to extend across an entire surface through the isolation structure 200.

For example, optionally, the material of the first sub-layer 201 includes a conductive material. The first sub-layer 201 is electrically connected to the second electrode 430 so that the second electrodes 430 of the multiple light-emitting units 400 can be interconnected into a surface electrode through the first sub-layer 201.

Optionally, the material of the second sub-layer 202 includes a conductive material. The second sub-layer 202 is electrically connected to the second electrode 430. This configuration aims to increase the distribution area of the conductive material and reduce voltage drops of second electrodes 430 at different positions in a display region AA.

In a possible embodiment, as shown in FIGS. 11 to 14, the isolation structure 200 further includes a second constant-width segment 154. The second constant-width segment 154 is located between adjacent isolation openings 210 and is configured to have a constant width. The width direction of the second constant-width segment 154 refers to the direction in which one of orthographic projections of the two adjacent isolation openings 210 on the array substrate 11 points towards the other.

In these optional embodiments, the isolation structure 200 further includes the second constant-width segment 154 between the two adjacent isolation openings 210. The second constant-width segment 154 is configured to have the constant width so that the light reflection capabilities at different positions on the second constant-width segment 154 tend to be consistent. Thus, the display effect of the display panel 1 can be improved.

The width direction of the second constant-width segment 154 refers to the direction in which one of the orthographic projections of the two isolation openings 210 on two sides of the second constant-width segment 154 on the array substrate 11 points towards the other. For example, the width direction of the second constant-width segment 154 refers to the direction in which the geometric center of one of the orthographic projections of the two isolation openings 210 on the two sides of the second constant-width segment 154 on the array substrate 11 points towards the geometric center of the other.

The width size of the first constant-width segment 153 and the width size of the second constant-width segment 154 may be configured in various manners. For example, the minimum width d1 of the first constant-width segment 153 and the minimum width d2 of the second constant-width segment 154 may be equal to each other, or d2≤2d1.

In these optional embodiments, the width of the first constant-width segment 153 is less than or equal to the width of the second constant-width segment 154. Thus, it can be ensured that the light-transmissive hole 220 has a sufficient opening area, thereby ensuring the transmittance of the display panel 1.

In addition, to ensure that the light-transmissive hole 220 has a sufficiently large opening area, the width of the first constant-width segment 153 is typically set to the minimum width within the range allowed by a process. When the minimum width d1 of the first constant-width segment 153 and the minimum width d2 of the second constant-width segment 154 satisfy that d2≤2d1, due to limitations in the preparation process, it is inappropriate to form the light-transmissive hole 220 on the second constant-width segment 154. Thus, adverse influence on the function of the isolation structure 200 is avoided.

In a possible embodiment, the second constant-width segment 154 includes a first sub-region and a second sub-region which are spaced apart and disposed side by side along the width direction of the second constant-width segment 154.

The relative positional relationship between the first sub-region and the second sub-region may be configured in various manners. For example, the first sub-region and the second sub-region are spaced apart and connected to each other through a connecting portion 1310 so that the distribution area of the isolation structure 200 is further reduced and the distribution area of the light-transmissive hole 220 is increased.

Alternatively, the first sub-region and the second sub-region are configured to be integral with each other. In addition, the sum of the minimum width of an orthographic projection of the first sub-region on the array substrate 11 and the minimum width of an orthographic projection of the second sub-region on the array substrate 11 is less than or equal to twice the minimum width d1 of the orthographic projection of the first constant-width segment 153 on the array substrate 11. This configuration aims to ensure that the integral first and second sub-regions are sufficiently narrow, thereby reducing the influence of the first and second sub-regions on the transmittance of the display panel 1.

In a possible embodiment, the minimum width of an orthographic projection of the connecting portion 1310 on the array substrate 11 is a third preset dimension D3. The third preset dimension D3 and the minimum width d1 of the orthographic projection of the first constant-width segment 153 on the array substrate 11 satisfy that D3=d1. Thus, the connecting portion 1310 is sufficiently narrow so that the distribution area of the isolation structure 200 is further reduced and the distribution area of the light-transmissive hole 220 is increased, thereby improving the transmittance of the display panel 1.

In a possible embodiment, the light-emitting units 400 include a first light-emitting unit 401, a second light-emitting unit 402, and a third light-emitting unit 403. The first light-emitting unit 401, the second light-emitting unit 402, and the third light-emitting unit 403 are in different colors.

Specifically, the first light-emitting unit 401 may be a blue light-emitting unit 400, the second light-emitting unit 402 may be a red light-emitting unit 400, and the third light-emitting unit 403 may be a green light-emitting unit 400.

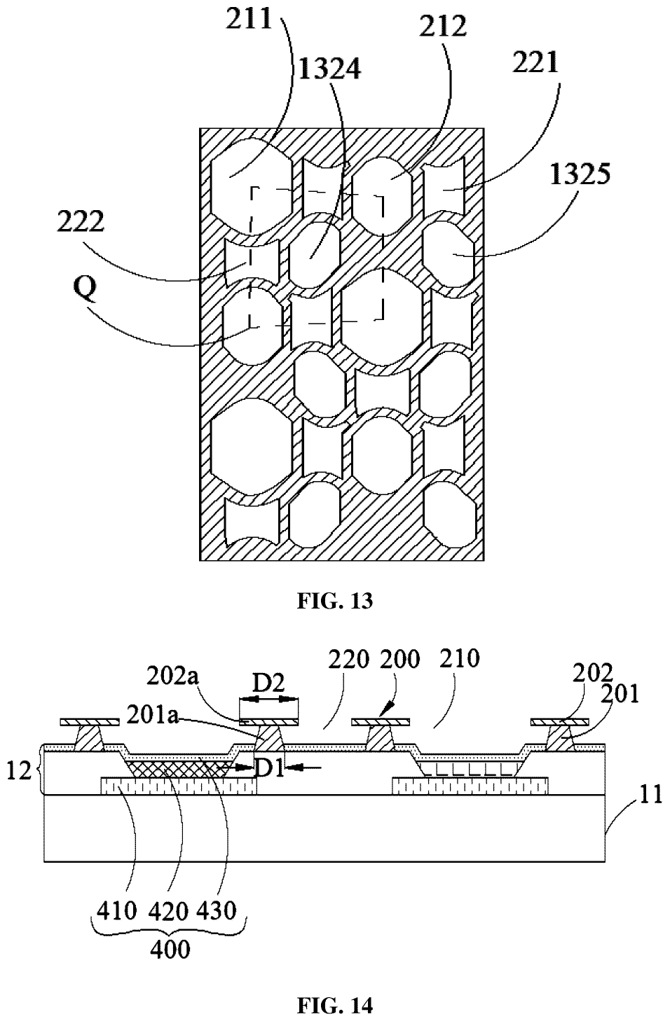

In a possible embodiment, as shown in FIGS. 13 and 14, the isolation openings 210 include a first isolation opening 211, a second isolation opening 212, and a third isolation opening 213. The first isolation opening 211 is configured to expose the first light-emitting unit 401, the second isolation opening 212 is configured to expose the second light-emitting unit 402, and the third isolation opening 213 is configured to expose the third light-emitting unit 403. First isolation openings 211 and second isolation openings 212 are alternately arranged along the second direction y to form a first opening column A1, where the first direction x intersects with the second direction y. Multiple third isolation openings 213 are arranged along the second direction y to form a second opening column A2. First opening columns A1 and second opening columns A2 are alternately arranged along the first direction X.

In the preceding embodiment, third light-emitting units 403 are disposed around a first light-emitting unit 401, third light-emitting units 403 are also disposed around a second light-emitting unit 402, and first light-emitting units 401 and second light-emitting units 402 are alternately disposed around a third light-emitting unit 403. Thus, a good light mixing effect can be achieved, and the light emission quality of the display panel 1 can be improved.

Optionally, at least one of the following is satisfied: the second constant-width segment 154 is disposed between the first isolation opening 211 and the third isolation opening 213, and the second constant-width segment 154 is disposed between a second isolation opening 212 and a third isolation opening 213 which are adjacent to each other.

In the preceding embodiment, the spacing between the first isolation opening 211 and the third isolation opening 213 is relatively small, and it is inappropriate to provide a light-transmissive hole 220 between the first isolation opening 211 and the third isolation opening 213. Therefore, the second constant-width segment 154 may be disposed between the first isolation opening 211 and the third isolation opening 213. Similarly, the spacing between the second isolation opening 212 and the third isolation opening 213 is relatively small, and it is inappropriate to provide a light-transmissive hole 220 between the second isolation opening 212 and the third isolation opening 213. Therefore, the second constant-width segment 154 may be disposed between the second isolation opening 212 and the third isolation opening 213.

For example, when the first light-emitting unit 401 is the blue light-emitting unit 400 and the second light-emitting unit 402 is the red light-emitting unit 400, the opening dimension of the second isolation opening 212 is smaller than the opening dimension of the first isolation opening 211. Therefore, the spacing between the first isolation opening 211 and the third isolation opening 213 is relatively small while the spacing between the second isolation opening 212 and the third isolation opening 213 is relatively large. Therefore, the second constant-width segment 154 between the first isolation opening 211 and the third isolation opening 213 and the second constant-width segment 154 between the second isolation opening 212 and the third isolation opening 213 may be configured in different manners.

For example, the second constant-width segment 154 includes the first sub-region and the second sub-region located between the first isolation opening 211 and the third isolation opening 213 which are adjacent to each other. The first sub-region and the second sub-region are spaced apart and connected to each other through the connecting portion 1310. The first sub-region and the second sub-region are spaced apart so that the distribution area of the isolation structure 200 can be further reduced and the distribution area of the light-transmissive hole 220 is increased, thereby improving the transmittance.

The second constant-width segment 154 includes the first sub-region and the second sub-region located between the second isolation opening 212 and the third isolation opening 213 which are adjacent to each other. The first sub-region and the second sub-region are configured to be integral with each other. In addition, the sum of the minimum width of the first sub-region and the minimum width of the second sub-region is less than or equal to 2d1. This configuration aims to ensure that the integral first and second sub-regions are sufficiently narrow, thereby reducing the influence of the first and second sub-regions on the transmittance of the display panel 1.

In the preceding embodiment, the third isolation opening 213 includes a first sub-opening 1324 and a second sub-opening 1325. The first sub-opening 1324 and the second sub-opening 1325 are alternately provided along the first direction x. Additionally, the first sub-opening 1324 and the second sub-opening 1325 which are adjacent to each other are symmetrically provided along an axis of symmetry parallel to the second direction y.

The third isolation opening 213 is configured in the preceding manner so that the third isolation opening 213 can be distributed with relatively high uniformity along the circumferential direction of the first isolation opening 211. Thus, the uniformity of the display panel 1 can be improved.

In addition, the third isolation opening 213 is configured in the preceding manner so that the third isolation opening 213 can be distributed with relatively high uniformity along the circumferential direction of the second isolation opening 212. Thus, the uniformity of the display panel 1 can be further improved.

In a possible embodiment, as shown in FIG. 13, first isolation openings 211 are located at two opposite vertices of a virtual quadrangle M1, and second isolation openings 212 are located at the other two opposite vertices of the virtual quadrangle M1. An orthographic projection of the shortest side edge of the virtual quadrangle M1 on the array substrate 11 does not overlap the orthographic projections of the light-transmissive holes 220 on the array substrate 11.

In the preceding embodiment, the distance between the first isolation opening 211 and the second isolation opening 212 which are adjacent to each other along the shortest side edge of the virtual quadrangle M1 is relatively small. To ensure the yield of the isolation structure 200, it is inappropriate to provide a light-transmissive hole 220 between the first isolation opening 211 and the second isolation opening 212 which are adjacent to each other.

First isolation openings 211 and second isolation openings 212 are alternately arranged along the first direction x to form a first opening row L1. In a possible embodiment, as shown in FIGS. 10 to 13, the light-transmissive holes 220 include first light-transmissive holes 221 and second light-transmissive holes 222. The first light-transmissive holes 221 is located between a first isolation opening 211 and a second isolation opening 212 in the first opening row L1. The second light-transmissive holes 222 is located between at least part of first isolation openings 211 and at least part of second isolation openings 212 in the first opening column A1. Light-transmissive holes 220 are provided in both the first opening row L1 and the first opening column A1 so that the distribution area of the light-transmissive holes 220 can be increased, thereby further improving the transmittance of the display panel 1.

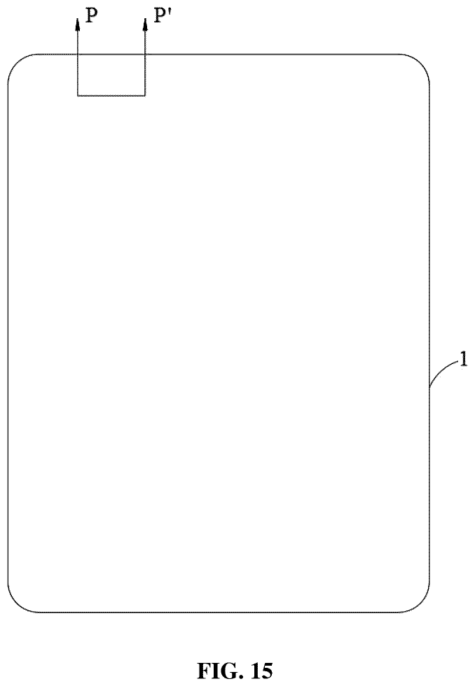

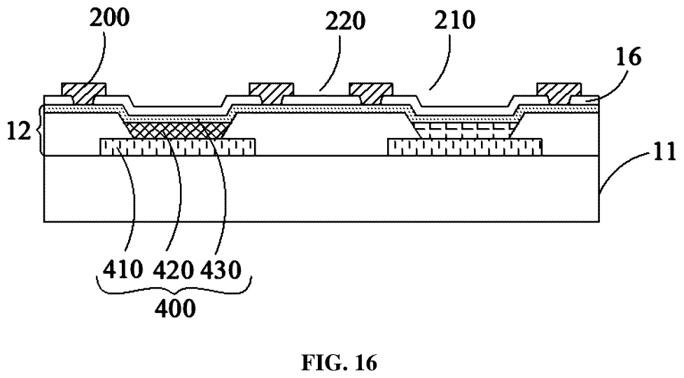

In other embodiments, as shown in FIGS. 15 and 16, the isolation structure 200 may be an auxiliary cathode. For example, the second electrode 430 is a surface electrode, and the isolation structure 200 is located on a side of the second electrode 430 facing away from the array substrate 11. An insulating layer 16 may be disposed between the isolation structure 200 and the second electrode 430. The isolation structure 200 and the second electrode 430 are connected to each other through vias.

The present application further provides another display panel 1. As shown in FIGS. 10 to 14, the display panel 1 includes an array substrate 11, a light-emitting layer 40, and an isolation structure 200. The light-emitting layer 40 is located on a side of the array substrate 11 and includes multiple light-emitting units 400. At least part of the isolation structure 200 encloses and forms isolation openings 210 and light-transmissive holes 220. The isolation openings 210 are configured to expose the light-emitting units 400. The light-transmissive hole 220 is formed between at least part of the isolation openings 210, where the at least part of the isolation openings 210 are adjacent to each other. The isolation structure 200 includes second constant-width segments 154 surrounding an isolation opening 210. At least an orthographic projection of the second constant-width segment 154 on the array substrate 11 is between orthographic projections of adjacent isolation openings 210 on the array substrate 11. The second constant-width segment 154 is configured to have a constant width. The width direction of the second constant-width segment 154 refers to the direction in which one of the orthographic projections of the two adjacent isolation openings 210 on the array substrate 11 points towards the other.

The preceding display panel 1 provided in the present application includes the array substrate 11, the light-emitting layer 40, and the isolation structure 200. The light-emitting layer 40 includes the multiple light-emitting units 400. The light-emitting units 400 are configured to emit light to implement the display function of the display panel 1. The isolation structure 200 further includes the second constant-width segment 154 between the two adjacent isolation openings 210. The second constant-width segment 154 is configured to have the constant width so that the light reflection capabilities at different positions on the second constant-width segment 154 tend to be consistent. Thus, the display effect of the display panel 1 can be improved.

In some optional embodiments, the isolation structure 200 further includes a first constant-width segment 153 located between a light-transmissive hole 220 and an isolation opening 210 which are adjacent to each other. The minimum width of an orthographic projection of the first constant-width segment 153 on the array substrate 11 is d1, and the minimum width of an orthographic projection of the second constant-width segment 154 on the array substrate 11 is d2, where d2≤2d1.

In these optional embodiments, the width of the first constant-width segment 153 is less than or equal to the width of the second constant-width segment 154. Thus, it can be ensured that the light-transmissive hole 220 has a sufficient opening area, thereby ensuring the transmittance of the display panel 1.

In addition, to ensure that the light-transmissive hole 220 has a sufficiently large opening area, the width of the first constant-width segment 153 is typically set to the minimum width within the range allowed by a process. When the minimum width d1 of the first constant-width segment 153 and the minimum width d2 of the second constant-width segment 154 satisfy that d2≤2d1, due to limitations in the preparation process, it is inappropriate to form the light-transmissive hole 220 on the second constant-width segment 154. Thus, adverse influence on the function of the isolation structure 200 is avoided.

In some optional embodiments, the second constant-width segment 154 includes a first sub-region and a second sub-region which are spaced apart along the direction in which one of the two adjacent isolation openings 210 points towards the other. The first sub-region and the second sub-region are spaced apart and connected to each other through a connecting portion 1310 so that the distribution area of the isolation structure 200 is further reduced and the distribution area of the light-transmissive hole 220 is increased.

Alternatively, the first sub-region and the second sub-region are configured to be integral with each other. In addition, the sum of the minimum width of an orthographic projection of the first sub-region on the array substrate 11 and the minimum width of an orthographic projection of the second sub-region on the array substrate 11 is less than or equal to 2d1. This configuration aims to ensure that the integral first and second sub-regions are sufficiently narrow, thereby reducing the influence of the first and second sub-regions on the transmittance of the display panel 1.

In some optional embodiments, the second constant-width segment 154 includes the first sub-region and the second sub-region which are spaced apart and connected to each other through the connecting portion 1310. The minimum width d3 of an orthographic projection of the connecting portion 1310 on the array substrate 11 and the minimum width d1 of the orthographic projection of the first constant-width segment 153 on the array substrate 11 satisfy that d3=d1. Thus, the connecting portion 1310 is sufficiently narrow so that the distribution area of the isolation structure 200 is further reduced and the distribution area of the light-transmissive hole 220 is increased, thereby improving the transmittance of the display panel 1.

In this embodiment, the configuration manners of the light-emitting units 400 and the isolation structure 200 are described above. The details are not repeated here. The display panel 1 in this embodiment may be cross-referenced with the display panel 1 in any one of the preceding embodiments.

The present application further provides another display panel 1. As shown in FIGS. 10 to 14, the display panel 1 has a first display region and a second display region which is disposed around at least part of the first display region. The display panel 1 includes an array substrate 11, a light-emitting layer 40, and an isolation structure 200. The light-emitting layer 40 is located on a side of the array substrate 11 and includes multiple light-emitting units 400. At least part of the isolation structure 200 encloses and forms isolation openings 210 and light-transmissive holes 220 located in the first display region. The isolation openings 210 are configured to expose the light-emitting units 400. The light-transmissive hole 220 is formed between at least part of the isolation openings 210, where the at least part of the isolation openings 210 are adjacent to each other. The isolation structure 200 includes first constant-width segments 153 surrounding a light-transmissive hole 220. At least an orthographic projection of the first constant-width segment 153 on the array substrate 11 is between an orthographic projection of the isolation opening 210 on the array substrate 11 and an orthographic projection of the light-transmissive hole 220 on the array substrate 11, where the isolation opening 210 and the light-transmissive hole 220 are adjacent to each other. The first constant-width segment 153 is configured to have a constant width. The width direction of the first constant-width segment 153 refers to the direction in which one of the orthographic projection of the light-transmissive hole 220 on the array substrate 11 and the orthographic projection of the isolation opening 210 on the array substrate 11 points towards the other.

In the embodiment of the present application, the light-transmissive holes 220 are provided in the first display region so that the transmittance of the first display region can be improved, thereby implementing under-screen integration of a photosensitive module in the first display region. The first constant-width segments 153 are disposed in the first display region. The first constant-width segment 153 is configured to have the constant width. That is, the part of the isolation structure 200 between the light-transmissive hole 220 and the isolation opening 210 is configured to have the constant width. On the premise that it can be ensured that the area of the isolation opening 210 remains constant and a preparation yield is ensured, the area of the light-transmissive hole 220 is increased as much as possible, thereby increasing the distribution area of the light-transmissive hole 220 and improving the transmittance of the display panel 1.

In this embodiment, the configuration manners of the light-emitting units 400 and the isolation structure 200 are described above. The details are not repeated here. The display panel 1 in this embodiment may be cross-referenced with the display panel 1 in any one of the preceding embodiments.

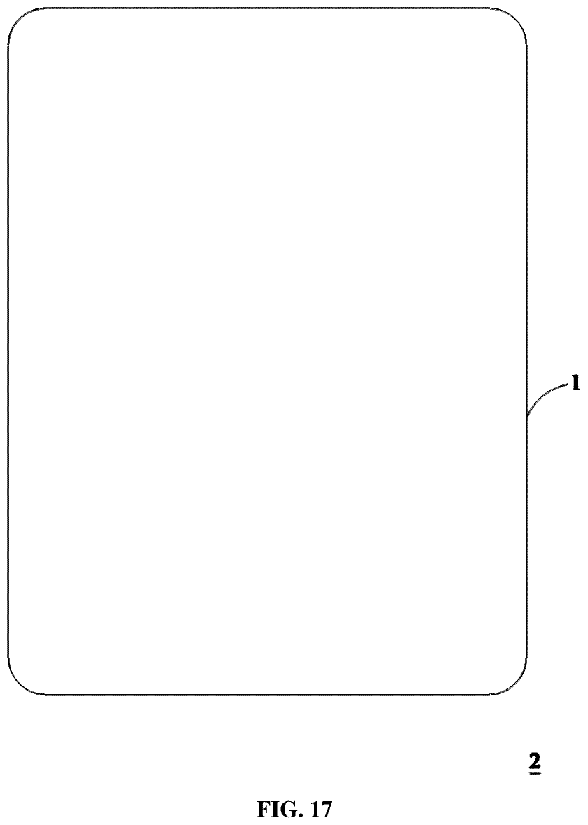

The present application further provides a display device 2. As shown in FIG. 17, the display device 2 includes any one of the display panels 1 provided in the preceding embodiments of the present application.

The display device 2 provided in the present application further includes a photosensitive module. The photosensitive module is integrated in the display panel 1 or located on a side of the array substrate 11 facing away from the light-emitting layer 40. The transmittance of the display panel 1 is improved. Thus, the photosensitive module can better receive light so that the working yield of the photosensitive module is improved.

In the embodiment of the present application, the display panel includes the array substrate 100 and the isolation structure 200. The isolation structure 200 encloses and forms the isolation openings 210 and the light-transmissive holes 220. The isolation opening 210 is configured to accommodate the light-emitting unit 400 so that the mutual crosstalk between adjacent light-emitting units 400 is reduced. Thus, the display panel emits light and performs a display. The array substrate 100 includes the substrate 120 and the metal structure 110 disposed on the substrate 120. The metal structure 110 may be configured to drive the light-emitting unit 400 to emit light. The light-transmissive holes 220 are configured to improve the transmittance of the display panel, thereby facilitating under-screen integration of the photosensitive module. The orthographic projection of the light-transmissive hole 220 on the substrate 120 is at least partially staggered from the orthographic projection of the metal structure 110 on the substrate 120. Thus, the influence of the metal structure 110 on the transmittance of the light-transmissive hole 220 can be reduced. Metal structures 110 corresponding to the peripheral side of the same isolation opening 210 in the substrate typically have different distribution shapes. The orthographic projections of the first light-transmissive hole 221 and the second light-transmissive hole 222 of the light-transmissive holes 220 on the substrate have different shapes. Thus, it is convenient for a user to reasonably configure the shape of the first light-transmissive hole 221 and the shape of the second light-transmissive hole 222 according to the distribution of the metal structures 110 in the substrate so that the dimension of the first light-transmissive hole 221 and the dimension of the second light-transmissive hole 222 are better adapted to the distribution shapes of the metal structures 110 in the substrate. The distribution area of the light-transmissive hole 220 is increased as much as possible. Additionally, the signal interference caused by the exposure of the metal structure 110 through the light-transmissive hole 220 is reduced, thereby improving the use performance of the display panel.

The display panel in the embodiment of the present application may be cross-referenced with the display panel in any one of the preceding embodiments. Optionally, the width of at least part of the first light-transmissive hole 221 in the first direction X is greater than the width of the second light-transmissive hole 222 in the first direction X. Thus, the dimension of the first light-transmissive hole 221 and the dimension of the second light-transmissive hole 222 are better adapted to the distribution shapes of the metal structures 110 in the substrate.

Optionally, the first light-transmissive hole 221 and the second light-transmissive hole 222 have the same extension length in the second direction Y so that the distribution shapes of the light-transmissive holes 220 are simplified, thereby facilitating the preparation and formation of the light-transmissive holes 220.

Optionally, the light-transmissive hole 220 has the preceding first side edge 230, and the isolating opening 210 has the preceding second side edge 240. The configuration manners of the first side edge 230 and the second side edge 240 are described above. The details are not repeated here. The light-transmissive hole 220 may further include the preceding first straight edge 220a. As shown in FIGS. 1 to 17, a display device is further provided in an embodiment in a second aspect of the present application. The display device includes the display panel 10 in any one of the preceding embodiments in the first aspect. The display device provided by the embodiment in the second aspect of the present application includes the display panel 10 in any one of the preceding embodiments in the first aspect. Therefore, the display device provided by the embodiment in the second aspect of the present application has the beneficial effects of the display panel 10 in any one of the preceding embodiments in the first aspect, and the details are not repeated here.

The display device in the embodiment of the present application includes but is not limited to devices with display functions, such as a mobile phone, a personal digital assistant (PDA), a tablet computer, an e-book, a television, an access control, an intelligent fixed-line telephone, and a console.

Although the present application has been described with reference to preferred embodiments, various modifications may be made and components therein may be replaced with equivalents without departing from the scope of the present application. In particular, the various technical features mentioned in the various embodiments may be combined in any manner as long as there is no structural conflict. The present application is not limited to the specific embodiments disclosed herein but includes all technical solutions falling within the scope of the claims.

What is claimed is:

1. A display panel, comprising:
an array substrate comprising a substrate and a metal structure disposed on the substrate;
an isolation structure disposed on a side of the array substrate, wherein the isolation structure encloses and forms a plurality of isolation openings and a plurality of light-transmissive holes, and an orthographic projection of a light-transmissive hole of the plurality of light-transmissive holes on the substrate is at least partially staggered from an orthographic projection of the metal structure on the substrate; and
light-emitting units configured to correspond to the plurality of isolation openings;
wherein the orthographic projection of the light-transmissive hole on the substrate comprises a recessed portion.

2. The display panel according to claim 1, wherein in at least one group of a light-transmissive hole and an isolation opening which are adjacent to each other, a direction in which a center of one of the light-transmissive hole and the isolation opening points towards a center of another of the light-transmissive hole and the isolation opening is a preset direction, and a minimum spacing between an edge of a recessed portion and an edge of the isolation opening in the preset direction is greater than or equal to a preset distance;
along the preset direction, in the at least one group of the light-transmissive hole and the isolation opening which are adjacent to each other, an orthographic projection of the isolation opening on the substrate comprises a protruding portion configured to correspond to the recessed portion; and
a shape of at least part of the protruding portion is adapted to a shape of at least part of the recessed portion.

3. The display panel according to claim 2, wherein for the light-transmissive hole and the isolation opening which are adjacent to each other, an orthographic projection of the recessed portion on the substrate has a first side edge facing the orthographic projection of the isolation opening on the substrate, an orthographic projection of the protruding portion on the substrate has a second side edge facing the first side edge, and a minimum distance between the first side edge and the second side edge along the preset direction is greater than or equal to the preset distance;
wherein the preset distance is 3 μm to 4 μm; and
a shape of at least part of the first side edge is adapted to a shape of the second side edge.

4. The display panel according to claim 3, wherein the first side edge and the second side edge are arc-shaped;
the light-transmissive hole is located on a side of the isolation opening in a first direction and has a first straight edge configured to face away from the first side edge along the first direction, and the first straight edge extends linearly along a second direction;
two ends of the first straight edge in the second direction are connected to second straight edges, and a second straight edge of the second straight edges extends linearly along the first direction;
a third straight edge is disposed on at least one side of the first side edge in the second direction, the third straight edge extends linearly along the second direction, and the first side edge is connected to the second straight edge through the third straight edge;
third straight edges are each disposed on two sides of the first side edge in the second direction, and two ends of the first side edge are connected to the second straight edges through the third straight edges; and
the first straight edge has a first median line extending along the first direction, and the first side edge is symmetrically disposed with respect to the first median line.

5. The display panel according to claim 3, wherein at least one light-transmissive hole of the plurality of light-transmissive holes has at least two recessed portions facing at least two isolation openings located on a peripheral side of the at least one light-transmissive hole, and each of the at least two recessed portions comprises a first side edge; and
a plurality of isolation openings are provided around the peripheral side of the at least one light-transmissive hole, at least two isolation openings of the plurality of isolation openings have protruding portions facing a same light-transmissive hole of the at least one light-transmissive hole, each of the protruding portions comprises a second side edge, and a shape of each second side edge is adapted to a shape of a corresponding first side edge.

6. The display panel according to claim 1, wherein the plurality of isolation openings comprise first isolation openings and second isolation openings, and the first isolation openings and the second isolation openings are alternately arranged along a first direction to form first opening groups; and
the plurality of light-transmissive holes comprise first light-transmissive holes and second light-transmissive holes, the first light-transmissive holes and the second light-transmissive holes are alternately arranged along the first direction, a first light-transmissive hole or a second light-transmissive hole is provided between a first isolation opening and a second isolation opening which are adjacent to each other, and at least one of the first light-transmissive hole and the second light-transmissive hole is provided with a recessed portion;
wherein the orthographic projection of the metal structure on the substrate is outside an orthographic projection of the first light-transmissive hole and an orthographic projection of the second light-transmissive hole on the substrate.

7. The display panel according to claim 6, wherein
the plurality of isolation openings further comprise third isolation openings, and a plurality of third isolation openings of the third isolation openings are arranged at intervals along the first direction to form a second opening group; and
the plurality of light-transmissive holes further comprise third light-transmissive holes, and a third light-transmissive hole is located between at least two adjacent third isolation openings.

8. The display panel according to claim 7, wherein the first opening groups and second opening groups are alternately arranged along a second direction, and the first opening groups and the second opening groups are staggered from each other to correspondingly locate the first isolation opening between two of the third isolation openings which are adjacent to each other along the first direction and at least one third light-transmissive hole is located on a side of the first isolation opening or the second isolation opening in the second direction.

9. The display panel according to claim 7, wherein two of the second isolation openings and two of the first isolation openings are provided on a peripheral side of the third isolation opening, and the two of the first isolation openings and the two of the second isolation openings are alternately arranged on the peripheral side of the third isolation opening; and
an orthographic projection of the third light-transmissive hole on the substrate has a smaller area than an orthographic projection of the first light-transmissive hole on the substrate or an orthographic projection of the second light-transmissive hole on the substrate.

10. The display panel according to claim 8, wherein the second opening group further comprises first gaps and second gaps, wherein the first gaps and the second gaps are located between two adjacent third isolation openings, the first gaps and the second gaps are alternately arranged along the first direction, and the third light-transmissive hole is located in a first gap of the first gaps;
conductive wires are further disposed on the substrate, wherein a wiring density of conductive wires in a region where the first gap is located is lower than a wiring density of conductive wires in a region where a second gap of the second gaps is located; and
an orthographic projection of at least one of the conductive wires on the substrate at least partially overlaps an orthographic projection of the third light-transmissive hole on the substrate.

11. The display panel according to claim 7, wherein the third light-transmissive hole comprises a third side edge facing a third isolation opening, the third isolation opening has fourth side edges facing the third side edge, and the third side edge and the fourth side edge are equally spaced;
the third side edge comprises a fifth sub-edge and a sixth sub-edge located on two sides of the third light-transmissive hole in the first direction;
the fourth side edge comprises a seventh sub-edge facing the fifth sub-edge and an eighth sub-edge facing the sixth sub-edge, the seventh sub-edge and the eighth sub-edge are located on two adjacent third isolation openings, the fifth sub-edge and the seventh sub-edge are equally spaced, and the sixth sub-edge and the eighth sub-edge are equally spaced;
the third light-transmissive hole has a second median line extending along a second direction, and the fifth sub-edge and the sixth sub-edge are symmetrically disposed with respect to the second median line; and
the third light-transmissive hole comprises a first segment and a second segment which are sequentially distributed along the second direction, the third side edge is disposed at the second segment, and a width of the first segment in the first direction is greater than or equal to a width of the second segment in the first direction.

12. The display panel according to claim 6, wherein
for the first light-transmissive hole and a first isolation opening and a second isolation opening which are located on two sides of the first light-transmissive hole, a distance from the first isolation opening to the first light-transmissive hole is not equal to a distance from the second isolation opening to the first light-transmissive hole; or
for the second light-transmissive hole and a first isolation opening and a second isolation opening which are located on two sides of the second light-transmissive hole, a distance from the first isolation opening to the second light-transmissive hole is not equal to a distance from the second isolation opening to the second light-transmissive hole; or
for the first isolation opening and a first light-transmissive hole and a second light-transmissive hole which are located on two sides of the first isolation opening, a distance from the first light-transmissive hole to the first isolation opening is not equal to a distance from the second light-transmissive hole to the first isolation opening; or
for the second isolation opening and a first light-transmissive hole and a second light-transmissive hole which are located on two sides of the second isolation opening, a distance from the first light-transmissive hole to the second isolation opening is not equal to a distance from the second light-transmissive hole to the second isolation opening.

13. The display panel according to claim 6, wherein
an orthographic projection of the first light-transmissive hole on the substrate has a larger area than an orthographic projection of the second light-transmissive hole on the substrate;
the plurality of isolation openings are distributed in an array along the first direction and a second direction, and the first light-transmissive hole and the second light-transmissive hole are located on two sides of a same isolation opening in the first direction;
the first light-transmissive hole and the second light-transmissive hole have a same length in the second direction; and
a width of at least part of the first light-transmissive hole in the first direction is greater than a width of the second light-transmissive hole in the first direction.

14. The display panel according to claim 1, further comprising:
a first encapsulation layer, wherein the first encapsulation layer comprises encapsulation portions which are spaced apart from each other to encapsulate the plurality of isolation openings, an avoidance gap is formed between adjacent encapsulation portions, and an orthographic projection of the avoidance gap on the substrate at least partially overlaps an orthographic projection of the light-transmissive hole on the substrate;
a second encapsulation layer located on a side of the first encapsulation layer facing away from the substrate, wherein orthographic projections of the plurality of light-transmissive holes on the substrate are within an orthographic projection of the second encapsulation layer on the substrate; and
a third encapsulation layer located on a side of the second encapsulation layer facing away from the substrate, wherein the orthographic projections of the plurality of light-transmissive holes on the substrate are within an orthographic projection of the third encapsulation layer on the substrate.

15. The display panel according to claim 1, further comprising a pixel defining layer, wherein the pixel defining layer comprises pixel defining portions and pixel openings, a pixel opening of the pixel openings communicates with an isolation opening of the plurality of isolation openings, and an orthographic projection of a light-transmissive hole of the plurality of light-transmissive holes on the substrate is within an orthographic projection of a pixel defining portion of the pixel defining portions on the substrate.

16. The display panel according to claim 1, comprising a display region, wherein the display region comprises a main display region and a light-transmissive display region, and the plurality of light-transmissive holes are located in the light-transmissive display region.

17. A display panel, comprising:
an array substrate comprising a substrate and a first active layer disposed on the substrate;
an isolation structure disposed on a side of the array substrate, wherein the isolation structure encloses and forms a plurality of isolation openings and a plurality of light-transmissive holes, and an orthographic projection of a light-transmissive hole of the plurality of light-transmissive holes on the substrate is at least partially staggered from an orthographic projection of the first active layer on the substrate; and
light-emitting units configured to correspond to the plurality of isolation openings.

18. The display panel according to claim 17, wherein the first active layer comprises a first channel region, and the orthographic projection of the light-transmissive hole on the substrate is staggered from an orthographic projection of the first channel region on the substrate; and
a material of the first active layer comprises a metal oxide semiconductor material.

19. The display panel according to claim 17, further comprising a second active layer, wherein an orthographic projection of the second active layer on the substrate is at least partially staggered from the orthographic projection of the light-transmissive hole on the substrate;
the second active layer comprises a second channel region, wherein an orthographic projection of the second channel region on the substrate is at least partially staggered from the orthographic projection of the light-transmissive hole on the substrate, or a light-shielding layer is disposed between the second channel region and the isolation structure and an orthographic projection of the second channel region on the substrate is within an orthographic projection of the light-shielding layer on the substrate;
a material of the second active layer comprises a low-temperature polycrystalline silicon semiconductor material;
the first active layer and the second active layer are disposed in different layers; and
the first active layer is located on a side of the second active layer facing away from the substrate.

20. The display panel according to claim 17, wherein in at least one group of a light-transmissive hole and an isolation opening which are adjacent to each other, a direction in which a center of one of the light-transmissive hole and the isolation opening points towards a center of another of the light-transmissive hole and the isolation opening is a preset direction, and a minimum spacing between an edge of a recessed portion and an edge of the isolation opening in the preset direction is greater than or equal to a preset distance;
along the preset direction, in the at least one group of the light-transmissive hole and the isolation opening which are adjacent to each other, an orthographic projection of the isolation opening on the substrate comprises a protruding portion configured to correspond to the recessed portion; and
a shape of at least part of the protruding portion is adapted to a shape of at least part of the recessed portion.
